(19) United States
(12) Patent Application Publication
(10) Pub. No.: US 2024/0061969 A1
(43) Pub. Date: Feb. 22, 2024

(54) BIM COMPONENT CREATING METHOD, DIGITAL DESIGN RESOURCE LIBRARY APPLICATION METHOD AND DEVICE

(71) Applicant: CHINA SW ARCHITECTURAL DES AND RES INST CORP. LTD, Chengdu (CN)

(72) Inventors: Changjian FANG, Chengdu (CN); Guangpo ZHAO, Chengdu (CN); Yongjun KANG, Chengdu (CN); Weiguo LONG, Chengdu (CN); Wei XIE, Chengdu (CN); Yifeng LAI, Chengdu (CN); Yijing ZHAO, Chengdu (CN)

(21) Appl. No.: 18/498,932

(22) Filed: Oct. 31, 2023

Related U.S. Application Data
(63) Continuation of application No. PCT/CN2023/099727, filed on Jun. 12, 2023.

(30) Foreign Application Priority Data
Jun. 13, 2022 (CN) 202210658876.X
Aug. 16, 2022 (CN) 202210977780.X
Aug. 17, 2022 (CN) 202210983786.8
Nov. 7, 2022 (CN) 202211381668.6
Nov. 29, 2022 (CN) 202211512160.5
Dec. 21, 2022 (CN) 202211650048.8

(51) Int. Cl. G06F 30/13

(52) U.S. Cl. CPC G06F 30/13

(57) ABSTRACT

The present disclosure provides a BIM component creating method, a digital design resource library application method, and a digital design resource library application device. By displaying recommended creation orders in a recommendation interface for a user to select, the user directly selects a recommended operation order in the recommendation interface, which, compared with selecting an order of next step from an order library, has higher selecting efficiency, and can improve the creating efficiency of the BIM component. Besides, in creation and application of a digital design resource library, a plurality of different creating modes are used for implementation. On the basis of improving the BIM component creating efficiency, the efficiency of creating the digital design resource library is further improved. Moreover, through bulk addition of parameters to the BIM component, geometric parameter visualization verification is performed on the BIM component.

### CROSS-REFERENCE TO RELATED APPLICATIONS

The present application is a continuation of International Application No. PCT/CN2023/099727 filed on Jun. 12, 2023 which claims benefit from Chinese patent application No. 202210658876.X filed with the China National Intellectual Property Administration on Jun. 13, 2022 and entitled “BIM Model Automatic Extraction Method and System, Electronic Equipment and Medium”, priority to the Chinese patent application No. 202210977780.X filed with the China National Intellectual Property Administration on Aug. 16, 2022 and entitled “Drive Verification Method and Device for BIM Component Parameterization Capability and Electronic Equipment”, priority to the Chinese patent application No. 202210983786.8 filed with the China National Intellectual Property Administration on Aug. 17, 2022 and entitled “BIM Component Recommendation Method and Device, and Electronic Equipment”, priority to the Chinese patent application No. 202211381668.6 filed with the China National Intellectual Property Administration on Nov. 7, 2022 and entitled “BIM Component Creating Method and Device, Storage Medium and Electronic Equipment”, priority to the Chinese patent application No. 202211512160.5 filed with the China National Intellectual Property Administration on Nov. 29, 2022 and entitled “BIM Model Building Method and Device, Computer Equipment and Readable Storage Medium”, and priority to the Chinese patent application No. 202211650048.8 filed with the China National Intellectual Property Administration on Dec. 21, 2022 and entitled “BIM Component Parameter Adding Method and Device, Storage Medium and Electronic Equipment”, the entire contents of which are hereby incorporated by reference in their entirety.

### TECHNOLOGICAL FIELD

The present disclosure relates to the technical field of building information, and in particular, to a BIM component creating method, and digital design resource library application method and device.

### BACKGROUND

Building Information Modeling (BIM) component resources, as a basic unit for constituting a BIM model, are transmission carriers of geometric information and non-geometric information of a BIM model, and also main contents of a BIM component resource library of a building engineering enterprise.

In the great trend of digital transformation for enterprises, accelerating deep fusion of digitization and full service chain of construction supported by the digital technology, and using BIM design in building projects are an irresistible trend. The BIM component resource library is one of the basic conditions for comprehensive application of the digital technology in the building engineering industry, and is a basic guarantee for realizing the digital transformation of production, management, and service in the building industry.

The component is the smallest data unit and geometric unit for constituting the BIM model, and is a minimum non-repeated item, in which a fixed value is determined in a project by one key attribute parameter or a set of a plurality of key attribute parameters in the project. An enterprise component resource library is a set of a plurality of components complying with the present standard, and when reflected in BIM software, such as Autodesk Revit software, is a set of a plurality of loadable BIM component files in .rfa format and complying with using standard. The BIM component is an element in modeling software, and meanwhile is also a carrier of parameter information. A plurality of attribute parameters of one BIM component may be corresponding to different values, and correspondingly form a plurality of BIM component types.

With regard to creation of the BIM component, due to its strong professionality, the creation of the BIM component has a big problem of low efficiency, and relatively high technical costs, so that only with some learning, practitioners are able to create the BIM component. Furthermore, the BIM component resource library related to building engineering currently in the world is still not mature, which lacks systematicness in aspects such as formation, management, and application of the BIM component resource library.

### GENERAL DESCRIPTION

Objectives of the present disclosure include, for example, providing a BIM component creating method, and digital design resource library application method and device, which can realize efficient and systematic formation and management of the resource library.
Embodiments of the present disclosure can be realized as follows.

In a first aspect, the present disclosure provides a BIM component creating method, wherein the method includes:
acquiring recommended creation orders based on a current creation order and transition probability information for creating a BIM component, wherein

the transition probability information includes execution probability of any next creation order after the current creation order, and the recommended creation orders include first preset number of creation orders ranked from high execution probability to low execution probability;
displaying the recommended creation orders in a recommendation interface; and

when any one of the recommended creation orders is determined as a new creation order, executing the new creation order.

In a second aspect, the present disclosure provides a digital design resource library application method, wherein the method includes:

creating a BIM component in a plurality of different creating modes, wherein the plurality of different creating modes include a BIM component creating mode based on automatic extraction by BIM model, a BIM component creating mode based on Rhino component conversion, and a BIM component creating mode based on any one of the preceding embodiments; and

performing, for a BIM component to which parameters need to be added, bulk addition of parameters on the BIM component, after a creator performing geometric parameter binding on the BIM component to which the parameters are added, performing geometric parameter visualization verification on the BIM component, and storing the verified BIM component in a digital design resource library.

In a third aspect, the present disclosure provides a BIM component creating device, wherein the device includes:

an acquiring unit, configured to acquire recommended creation orders based on a current creation order and transition probability information for creating a BIM component,

wherein the transition probability information includes execution probability of any next creation order after the current creation order, and the recommended creation orders include first preset number of creation orders ranked from high execution probability to low execution probability;

a displaying unit, configured to display the recommended creation orders in a recommendation interface; and

an executing unit, configured to, when any one of the recommended creation orders is determined as a new creation order, execute the new creation order.

In a fourth aspect, the present disclosure provides a digital design resource library application device, wherein the device includes:

a creating unit, configured to create a BIM component in a plurality of different creating modes, wherein the plurality of different creating modes include a BIM component creating mode based on automatic extraction by BIM model, a BIM component creating mode based on Rhino component conversion, and a creating mode realized by the BIM component creating device according to the preceding embodiment; and

an application unit, configured to perform, for a BIM component to which parameters need to be added, bulk addition of parameters on the BIM component, and after a creator performing geometric parameter binding on the BIM component to which the parameters are added, perform geometric parameter visualization verification on the BIM component, and store the verified BIM component in a digital design resource library.

The embodiments of the present disclosure include, for example, the following the beneficial effects.

The present disclosure provides a BIM component creating method, a digital design resource library application method, and a digital design resource library application device, wherein when creating the BIM component, by displaying the recommended creation orders in the recommendation interface for the user to select, the user directly selects a recommended operation order in the recommendation interface, which, compared with selecting the order of the next step from an order library, has higher selecting efficiency, and reduced requirements to technical costs, and further can improve the creating efficiency of the BIM component.

Further, when creating and applying the digital design resource library, creation is performed in a plurality of different BIM component creating modes, including the BIM component creating mode based on automatic extraction by BIM model, the BIM component creating mode based on Rhino component conversion, and the BIM component creating mode based on a recommended creation order. The efficiency of creating the digital design resource library can be further improved on the basis of improving the efficiency of creating the BIM component. Moreover, through bulk addition of parameters to the BIM component, after the creator performs geometric parameter binding on the BIM component to which the parameters are added, the geometric parameter visualization verification is performed on the BIM component, the verified BIM component is stored in a digital design resource library. In this way, the parameter bulk addition to the BIM component and parametrization capability verification can be effectively realized, and further formation and management of the digital design resource library can be realized efficiently and systematically.

### BRIEF DESCRIPTION OF DRAWINGS

In order to more clearly illustrate technical solutions of embodiments of the present disclosure, drawings which need to be used in the embodiments will be introduced briefly below, and it should be understood that the drawings below merely show some embodiments of the present disclosure, therefore, they should not be considered as limitation to the scope, and a person ordinarily skilled in the art further could obtain other relevant drawings according to these drawings, without using any inventive efforts.

FIG. 1 is a flowchart of a digital design resource library application method provided in an embodiment of the present disclosure;

FIG. 2 is a schematic diagram of a general technical route of the digital design resource library application method provided in an embodiment of the present disclosure;

FIG. 3 is another flowchart of the digital design resource library application method provided in an embodiment of the present disclosure;

FIG. 4 is a flowchart of a BIM component creating method provided in an embodiment of the present disclosure;

FIG. 5 is a schematic diagram of a general technical route of BIM component creation based on a recommended creation order provided in an embodiment of the present disclosure;

FIG. 6 is a schematic diagram of a BIM component creation command recommendation system of a Markov chain transition probability matrix provided in an embodiment of the present disclosure;

FIG. 7 is a schematic diagram of a setting and operation interface of a BIM component creation software system based on a Markov chain provided in an embodiment of the present disclosure;

FIG. 8 is a schematic diagram of using effect of the BIM component creation software system based on a Markov chain provided in an embodiment of the present disclosure;

FIG. 9 is a flowchart of sub steps contained in step S11 in FIG. 1;

FIG. 10 is a schematic diagram of a general technical route of automatic extraction by BIM model provided in an embodiment of the present disclosure;

FIG. 11 is a schematic diagram of a BIM component naming standard provided in an embodiment of the present disclosure;

FIG. 12 is another flowchart of the substeps contained in step S11 in FIG. 1;

FIG. 13 is a schematic diagram of a general technical route of converting a Rhino component to a BIM component provided in an embodiment of the present disclosure;

FIG. 14 is a first schematic format defined for an object in a ply file provided in an embodiment of the present disclosure;

FIG. 15 is a second schematic format defined for an object in a ply file provided in an embodiment of the present disclosure;

FIG. 16 shows schematic algorithm codes for converting a 3dm format file to a ply format file provided in an embodiment of the present disclosure;

FIG. 17 shows schematic codes of the algorithm for parsing the ply format file provided in an embodiment of the present disclosure;

FIG. 18 is a flowchart of substeps contained in step S12 in FIG. 1;

FIG. 19 is a schematic diagram of a plug-in interface of a BIM component modification module provided in an embodiment of the present disclosure;

FIG. 20 is a schematic diagram of a parameter information interface of a plug-in of the BIM component modification module provided in an embodiment of the present disclosure;

FIG. 21 is a flowchart of substeps contained in step S13 in FIG. 1;

FIG. 22 is a schematic diagram of a general technical route of BIM component parameter visualization verification provided in an embodiment of the present disclosure;

FIG. 23 is a schematic diagram of a parameter set of the BIM component provided in an embodiment of the present disclosure;

FIG. 24 is a schematic diagram of a JSON format dataset of the BIM component provided in an embodiment of the present disclosure;

FIG. 25 is a schematic diagram of dynamically assigning BIM component parameters to variables provided in an embodiment of the present disclosure;

FIG. 26 is a schematic diagram of a drive checking interface for BIM component visualization data provided in an embodiment of the present disclosure;

FIG. 27 is a schematic diagram of illustration of a drive checking software interface for BIM component visualization data provided in an embodiment of the present disclosure;

FIG. 28 is a schematic diagram of a using process of drive verification software provided in an embodiment of the present disclosure;

FIG. 29 is a flowchart of substeps contained in step S14 in FIG. 3;

FIG. 30 is a schematic diagram of a general technical route of BIM component recommendation based on cosine similarity provided in an embodiment of the present disclosure;

FIG. 31 is a schematic diagram of a data section creation process provided in an embodiment of the present disclosure;

FIG. 32 is a schematic diagram of illustration of acquiring other relevant component data in a data section provided in an embodiment of the present disclosure;

FIG. 33 is a schematic diagram of a BIM component application scenario dataset component collection system provided in an embodiment of the present disclosure;

FIG. 34 is a schematic diagram of an application scenario-based BIM component recommendation system provided in an embodiment of the present disclosure;

FIG. 35 is a flowchart of substeps contained in step S15 in FIG. 3;

FIG. 36 is a schematic diagram of data placeholders and data placeholding view provided in an embodiment of the present disclosure;

FIG. 37 is a schematic diagram of an initial interface of a plug-in related to BIM model building based on data placeholding provided in an embodiment of the present disclosure;

FIG. 38 is a schematic diagram of 4 areas of the plug-in related to the BIM model building based on data placeholding provided in an embodiment of the present disclosure;

FIG. 39 is a schematic diagram of a standard Cartesian coordinate system provided in an embodiment of the present disclosure;

FIG. 40 is a visualization schematic diagram of a first-class placeholder provided in an embodiment of the present disclosure;

FIG. 41 is a visualization schematic diagram of a second-class placeholder provided in an embodiment of the present disclosure;

FIG. 42 is a schematic diagram of a rendering result instance of data placeholders provided in an embodiment of the present disclosure;

FIG. 43 is an overall flowchart of the BIM model building based on data placeholding provided in an embodiment of the present disclosure;

FIG. 44 is a schematic diagram of cooperation of a rendering area with a visualization area and a viewing area provided in an embodiment of the present disclosure;

FIG. 45 is a schematic diagram of cooperation of the visualization area with the rendering area and the viewing area provided in an embodiment of the present disclosure;

FIG. 46 shows a first manner of using the plug-in of the BIM model building based on data placeholding provided in an embodiment of the present disclosure;

FIG. 47 shows a second manner of using the plug-in of the BIM model building based on data placeholding provided in an embodiment of the present disclosure;

FIG. 48 is a structural block diagram of electronic equipment provided in an embodiment of the present disclosure;

FIG. 49 is a block diagram of functional modules of a BIM component creating device provided in an embodiment of the present disclosure; and

FIG. 50 is a block diagram of functional modules of a digital design resource library application device provided in an embodiment of the present disclosure.

### DETAILED DESCRIPTION OF EMBODIMENTS

In order to make objectives, technical solutions, and advantages of the embodiments of the present disclosure clearer, the technical solutions in the embodiments of the present disclosure will be described clearly and completely below in conjunction with drawings in the embodiments of the present disclosure, and apparently, the embodiments described are some but not all embodiments of the present disclosure. Generally, components in the embodiments of the present disclosure, as described and shown in the drawings herein, may be arranged and designed in various different configurations.

Therefore, the detailed description below of the embodiments of the present disclosure provided in the drawings is not intended to limit the claimed scope of the present disclosure, but merely illustrates chosen embodiments of the present disclosure. All of other embodiments obtained by those of ordinary skill in the art based on the embodiments of the present disclosure without using any inventive efforts shall fall within the scope of protection of the present disclosure.

It should be noted that similar reference signs and letters represent similar items in the following drawings, therefore, once a certain item is defined in one drawing, it is not needed to be defined or explained in subsequent drawings.

It should be noted that the features in the embodiments of the present disclosure may be combined with each other without conflict.

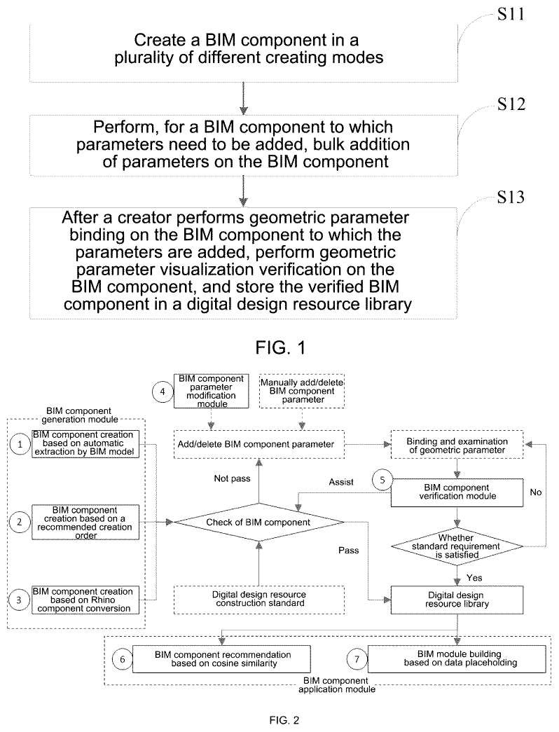

An embodiment of the present disclosure provides a digital design resource library application method, wherein this method can be executed by a digital design resource library application device, and this device can be realized by means of software and/or hardware. The device can be configured in a terminal. As shown in FIG. 1, this method includes the following steps.

S11, creating a BIM component in a plurality of different creating modes.

In the above, the plurality of different creating modes include a BIM component creating mode based on automatic extraction by BIM model, a BIM component creating mode based on Rhino component conversion, and a BIM component creating mode based on a recommended creation order.

S12, performing, for a BIM component to which parameters need to be added, bulk addition of parameters on the BIM component.

S13, after a creator performing geometric parameter binding on the BIM component to which the parameters are added, performing geometric parameter visualization verification on the BIM component, and storing the verified BIM component in a digital design resource library.

In the present embodiment, when creating the digital design resource library, the creation is performed in a plurality of different BIM component creating modes, including the BIM component creating mode based on automatic extraction by BIM model, the BIM component creating mode based on Rhino component conversion, and the BIM component creating mode based on a recommended creation order. The efficiency of creating the digital design resource library can be further improved on the basis of improving the efficiency of creating the BIM component. Moreover, through bulk addition of parameters to the BIM component, after the creator performs geometric parameter binding on the BIM component to which the parameters are added, the geometric parameter visualization verification is performed on the BIM component, the verified BIM component is stored in a digital design resource library. In this way, the parameter bulk addition to the BIM component and parametrization capability verification can be effectively realized, and further formation and management of the digital design resource library can be realized efficiently and systematically.

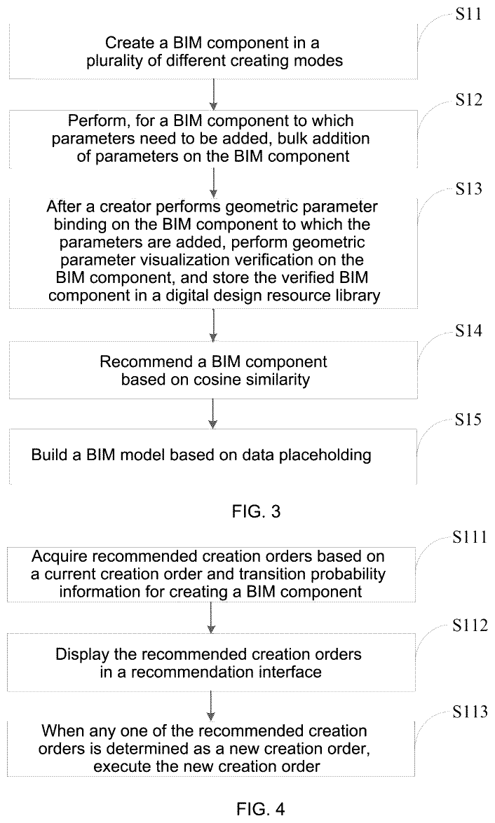

Referring to FIG. 2 and FIG. 3 in combination, the digital design resource library application method provided in the present embodiment further includes the following steps:

S14, recommending a BIM component based on cosine similarity; and

S15, building a BIM model based on data placeholding.

In the above, as shown in FIG. 2, the above creation of the BIM component can be realized by a BIM component generation module, including, for example, BIM component creation based on automatic extraction by BIM model, BIM component creation based on a recommended creation order, and BIM component creation based on Rhino component conversion. The bulk addition of parameters can be added to the BIM component by a BIM component modification module, and the geometric parameter visualization verification on the BIM component can be realized by a BIM component verification module. In addition, there is also a BIM component application module, configured to recommend the BIM component based on cosine similarity and build the BIM model based on data placeholding.

It can be seen from the above that in the process of creating and applying the digital design resource library, the creation of the BIM component is involved first. The creation of the BIM component can be realized in a plurality of creating modes, one of which is a BIM component creating method based on a recommended creation order. An implementation mode of the BIM component creating method based on the recommended creation order is introduced first below.

Referring to FIG. 4, it is a flowchart of a BIM component creating method provided in an embodiment of the present disclosure, and this creating method is a BIM component creating method based on a recommended creation order. This method can be executed by a BIM component creating device, wherein this device can be realized by means of software and/or hardware, and this device can be configured in a terminal. As shown in FIG. 4, this method includes the following steps.

S111, acquiring recommended creation orders based on a current creation order and transition probability information for creating a BIM component.

In the above, the transition probability information includes execution probability of any next creation order after the current creation order, and the recommended creation orders include first preset number of creation orders ranked from high execution probability to low execution probability.

S112, displaying the recommended creation orders in a recommendation interface.

S113, when any one of the recommended creation orders is determined as a new creation order, executing the new creation order.

In the present embodiment, the current creation order can be acquired from a BIM software application programming interface (API) of BIM software. Optionally, the transition probability information is a Markov chain transition probability matrix. In the present embodiment, the BIM software may be, but is not limited to, Revit software.

It should be understood that in the process of creating the BIM component, the user selects different creation orders with greater randomness. It can be assumed that the creation order of the BIM component used at a next moment is only related to the creation order at a previous moment, the number of creation orders of the BIM component provided by the BIM software is limited, the user's selection of creation order at different moments is also limited, which means that Markov chain transition states are limited. It may be further interpreted that, for any two successive moments Xₜ and Xₜ₊₁, the user uses order_{f} at the moment Xₜ, then the probability for the user using order_{g} at the moment Xₜ₊₁ is p(f, g), where f and g are numbers of any two BIM component operation commands.

Therefore, a Markov chain transition probability matrix P is constructed as follows, and any p is an unknown number.

| | | | | | | | |
|---|---|---|---|---|---|---|---|
| | order₁ | order₂ | . . . | orderₗ | . . . | orderₛ₋₁ | orderₛ |
| order₁ | p (1, 1) | p (1, 2) | . . . | p (1, l) | . . . | p (1, s − 1) | p (1, l) |
| order₂ | p (2, 1) | p (2, 2) | . . . | p (2, l) | . . . | p (2, s − 1) | p (2, l) |
| . . . | . . . | . . . | . . . | . . . | . . . | . . . | . . . |
| orderₗ | p (l, 1) | p (l, 2) | . . . | p (l, l) | . . . | p (l, s − 1) | p (l, s) |
| | . . . | . . . | . . . | . . . | . . . | . . . | . . . |
| orderₛ₋₁ | p (s − 1, l) | p (s − 1, 2) | . . . | p (s − 1, l) | . . . | p (s − 1, s − 1) | p (s − 1, s) |
| orderₛ | p (s, 1) | p (s, 2) | . . . | p (s, l) | . . . | p (s, s − 1) | p (s, s) |

In the above, orderₗ represents an lth creation order, s represents the total number of creation orders used by the user in the process of creating the BIM component, and p(f, g) represents probability of executing the creation order (order_{g}) after the creation order (orderₗ), or execution probability of the creation order (order_{g}) after the creation order (orderₗ).

The above Markov chain transition probability matrix P has two features:
1) 0≤p(f, g)≤1, where (f, g=1, 2, . . . , s) that is, a value range of any p(f, g) is [0,1]; and
2)

$${\sum }_{f = 1}^{s} p ( f , g ) = 1 ,$$

where (f=1, 2, . . . , s), i.e. the sum of transition probabilities in each line in the matrix is 1.

It should be understood that, on the basis of the current creation order and transition probability information, the execution probability of any next creation order after the current creation order can be learned, and further the recommended creation orders can be determined.

Optionally, the preset number may be greater than or equal to 1, for example, the creation order with the highest execution probability is selected as the recommended creation order, or the creation orders with top 5 execution probabilities are selected as the recommended creation orders.

Certainly, the transition probability information can be presented in the form of matrix, and also can be presented in other forms, for example, a set, a sequence, and a table, which is not limited herein.

Optionally, the recommendation interface can be displayed by a displayer, and the recommendation interface may be a plug-in interface. The recommended creation orders are displayed in the recommendation interface, for reference of the user, thus facilitating the user in selecting a creation order of next step.

By displaying the recommended creation orders in the recommendation interface for the user to select, the user directly selects a recommended operation order in the recommendation interface, which, compared with selecting the order of the next step from an order library, has higher selecting efficiency, and reduced requirements to technical costs, and further can improve the creating efficiency of the BIM component.

Optionally, the new creation order can be executed by corresponding BIM software. Optionally, the new creation order is a to-be-executed creation order.

From the above, for the BIM component creating method based on a recommended creation order provided in the present embodiment, by displaying the recommended creation orders in the recommendation interface for the user to select, the user directly selects a recommended operation order in the recommendation interface, which, compared with selecting the order of the next step from the order library, has higher selecting efficiency, and reduced requirements to technical costs, and further can improve the creating efficiency of the BIM component.

It should be understood that, in the next cycle, the newly executed creation order may serve as a new current creation order, and the recommendation of creation order is performed repeatedly.

Optionally, according to characteristics of Markov chain model transition probability matrix, a probability matrix of transferring the state order_{f} by x steps is:

P(x)=p(order_{f})P^{x} (1)

Markov chain probability distribution is completely determined by one-step probability matrix p(1) and initial distribution probability p(order_{f}) thereof, that is, any operation command used in the process of creating the BIM component by the user is only related to initially formed transition probability matrix and initial distribution, while the initial state is known for the command recommendation, and only all possible commands for executing the next step and probabilities thereof need to be considered.

The transition probability of transferring order_{f} to the state order_{g} by x steps is p(f, g), i.e.,fth line and gth column of P(x).

For the recommendation of BIM component creation commands, only the probability matrix P(1) of obtaining the next state by 1 step of transition needs to be considered, and further all probability values of the current operation command order_{f} to be transferred to any other operation command can be acquired from the probability matrix P(1) as follows:

P(f)=[p(f,1) p(f,2) . . . p(f,1) , , , p(f,s−1) p(f,s)]

The first preset number of creation orders ranked from high execution probability to low execution probability in P(f) are obtained as the recommended creation orders. According to orderₗ={nameₗ,,idₗ}, a command name and a command id of the next execution command can be obtained, the command name can be provided for the user to select, and the command id is used as an input parameter for executing the next command.

With regard to how to acquire transition probability information, the present embodiment further provides a possible implementation mode, i.e., before acquiring recommended creation orders based on a current creation order and transition probability information for creating a BIM component, the BIM component creating method further includes the following steps:

acquiring a log record of BIM component creation of the creator, wherein the log record includes historical creation orders used by the creator in the process of creating the BIM component and a sequence of executing the historical creation orders, determining all historical creation orders based on the log record, and counting a frequency of occurrence of any order combination in the log record, wherein the order combination is a combination of any two adjacent historical creation orders; counting the number of combinations corresponding to any historical creation order in the log record, wherein the number of combinations is the number of order combinations with the historical creation order as a first order therein; and based on the frequency and the number of combinations, determining execution probability of any historical creation order after each historical creation order, so as to generate the transition probability information.

Optionally, the creator can be the user himself/herself, and also can be an example object with relatively high BIM component efficiency. In order to make data more representative and conform to user's habit, as many log records of the same user as possible can be collected, and the created transition probability information can improve the user experience.

Optionally, it is possible to only acquire log records within a preset period of time. It should be understood that the number of log records may not be 1, for example, m log records corresponding to m log files acquired for BIM component creation.

Optionally, any BIM component creation order in any log record is defined as:

commandᵢⱼ_{ᵢ}={nameᵢⱼ_{ᵢ},idᵢⱼ_{ᵢ}}

where i represents an ith log record of the BIM component creation, with a value range of {1, m}, where m represents the total number of log records; jᵢ represents a jth creation order in the ith log record, with a value range of {1, nᵢ}, where n, represents the total number of creation orders in the ith log record.

A BIM component creation order sequence in one log record of BIM component creation is expressed by squenceᵢ, one order sequence is formed after one log record is traversed, and the creation orders read in the traversing process are stored in the squenceᵢ, and squenceᵢ contains a plurality of creation orders commandᵢⱼ_{ᵢ}={nameᵢⱼ_{ᵢ},idᵢⱼ_{ᵢ}}.

Referring to Table 1 below, Table 1 is used to show part of the acquired creation orders in one log record.

TABLE 1
BIM Component Operation Commands

| No. | Command type | Command name | Command id |
|---|---|---|---|
| 1 | Jrn.CommandRibbon | Create object by orthogonally | ID_OBJECTS_EXTRUSION |
| | | stretching sketch | |
| 2 | Jrn.CommandRibbon | Create rectangle | ID_OBJECTS_CURVE_RECT |
| 3 | Jrn.CommandAccel | Cancel current operation | ID_CANCEL_EDITOR |
| | Key | | |
| 4 | Jrn.CommandAccel | Cancel current operation | ID_CANCEL_EDITOR |
| | Key | | |
| 5 | Jrn.CommandAccel | Cancel current operation | ID_CANCEL_EDITOR |
| | Key | | |
| 6 | Jrn.CommandRibbon | Finish sketch | ID_FINISH_SKETCH |
| 7 | Jrn.CommandRibbon | Create object by orthogonally | ID_OBJECTS_EXTRUSION |
| | | stretching sketch | |
| 8 | Jrn.CommandRibbon | Create rectangle | ID_OBJECTS_CURVE_ |
| | | | RECT |
| 9 | Jrn.CommandAccel | Cancel current operation | ID_CANCEL_EDITOR |
| | Key | | |
| 10 | Jrn.CommandAccel | Cancel current operation | ID_CANCEL_EDITOR |
| | Key | | |
| 11 | Jrn.CommandAccel | Undo last operation | ID_EDIT_UNDO |
| | Key | | |
| 12 | Jrn.CommandRibbon | Create line | ID_EDIT_MIRROR_LINE |
| 13 | Jrn.CommandAccel | Cancel current operation | ID_CANCEL_EDITOR |
| | Key | | |
| 14 | Jrn.CommandAccel | Cancel current operation | ID_CANCEL_EDITOR |
| | Key | | |
| 15 | Jrn.CommandRibbon | Mirror selected object | ID_EDIT_MIRROR |
| 16 | Jrn.CommandAccel | Cancel current operation | ID_CANCEL_EDITOR |
| | Key | | |
| . . . | . . . | . . . | . . . |
| 145 | Jrn.CommandAccel | Save active item | ID_REVIT_FILE_SAVE |
| | Key | | |
| 146 | Jrn.CommandSyste | Exit application; prompt | ID_APP_EXIT |
| | mMenu | saving item | |

After all log records are traversed, m order sequences are formed, the order sequences squenceᵢ formed by individual log records are gathered, and the m order sequences are gathered into squence, so as to acquire the creation orders in all log records of the BIM component creation, and all the gathered order sequences squence of the log records of the BIM component creation can be expressed as follows.

$$sequence = \{ \begin{matrix}sequ {ence}_{1} \\ … \\ s e q u e n c {e}_{i} \\ … \\ s e q u e n c {e}_{m}\end{matrix} \} = \{ \begin{matrix}{command}_{11} , … , {command}_{{1}_{{j}_{1}}} , … , {command}_{1 {n}_{1}} \\ … … \\ {command}_{i 1} , … , {command}_{{ij}_{i}} , … , {command}_{{in}_{i}} \\ … … \\ {command}_{m 1} , … , {command}_{{mj}_{i}} , … , {command}_{{mn}_{m}}\end{matrix} \}$$

That is, any BIM component order squence, is corresponding to a corresponding group of BIM component creation orders commandᵢⱼ_{ᵢ} (i=1, 2, . . . , m; j=1, 2, . . . , nₘ).

On the basis of acquiring the squence, all two-dimensional order sequences squence can be dimension-reduced to one-dimensional space, that is, squenceᵢ is cyclically taken out and spliced in sequence, to form a first order set T expressed as follows:

T={command₁₁, . . . , commandᵢⱼ_{ᵢ}, . . . , commandₘₙ_{ₘ}}

After all repeated creation orders in the first order set T are removed, S creation orders are reserved in total, and a second order set Q containing all the creation orders to be used in the process of creating the BIM component is obtained, expressed as follows:

Q={order₁, . . . , order_{f}, . . . , order_{g}, . . . , orderₛ}

where orderₗ represents an lh creation order in the second order set Q, which is different for any order_{f} and order_{g}.

orderₗ={nameₗidₗ}

In the above, name represents name of the creation order, and id represents id of the creation order.

It should be understood that, the creation orders in the second order set Q are all historical creation orders.

It should be understood that two historical creation orders in the same order combination may be the same or different.

Optionally, due to randomness of user operation or complexity of creating a BIM component command, distribution of any command commandᵢⱼ_{ᵢ} in the BIM component operation sequence sequenceᵢ has certain randomness and repeatability, and there must exist commandᵢⱼ_{ᵢ}=orderₗ. Therefore, the BIM component operation sequence squenceᵢ needs to be read cyclically, and commandᵢⱼ_{ᵢ} and next command appearing thereafter are counted iteratively, that is, frequency of occurrence of a command combination (commandᵢⱼ_{ᵢ}, commandᵢ₍ⱼ₊₁₎,) is counted, and the counted order combination sequence is recorded as O, expressed as follows:

$$O = \{ \begin{matrix}{O}_{1} \\ … \\ {O}_{i} \\ … \\ {O}_{m}\end{matrix} \} = \{ \begin{matrix}( {command}_{11} , {command}_{12} ) , … , ( {command}_{1 {j}_{1}} , {command}_{1 {( j + 1 )}_{1}} ) , … , {command}_{1 {( n - 1 )}_{1}} , {command}_{1 {n}_{1}} ) \\ … \\ ( {command}_{i 1} , {command}_{i 2} ) , … , ( {command}_{{ij}_{i}} , {command}_{{i ( j + 1 )}_{i}} ) , … , {command}_{{i ( j - 1 )}_{i}} , {command}_{{in}_{i}} ) \\ … \\ ( {command}_{m 1} , {command}_{m 2} ) , … , ( {command}_{{mj}_{m}} , {command}_{{m ( j + 1 )}_{m}} ) , … , {command}_{{m ( j - 1 )}_{m}} , {command}_{{mn}_{m}} )\end{matrix} \}$$

The order combination sequence O contains situations of any order combination (commandᵢⱼ_{ᵢ}, commandᵢ₍ⱼ₊₁₎_{ᵢ}) in the log record of BIM component creation operation, and in order to facilitate in counting all order combination situation and corresponding number thereof, all order combination sequences are spliced, cyclically taken out and spliced, so that an order sequence set S of one-dimensional space can be obtained.

The order combination sequence O contains situations of any order combination (commandᵢⱼ_{ᵢ}, commandᵢ₍ⱼ₊₁₎_{ᵢ}) in the log record of BIM component creation operation, and in order to facilitate in counting all order combination situation and corresponding number thereof, all order combination sequences are spliced, cyclically taken out and spliced, so that an order sequence set S of one-dimensional space can be obtained.

$$S = \{ \begin{matrix}( {command}_{11} , {command}_{12} ) , … , \\ ( {command}_{{ij}_{i}} , {command}_{{i ( j + 1 )}_{i}} ) , … , \\ {command}_{{m ( n - 1 )}_{m}} , {command}_{{mn}_{m}} )\end{matrix} \}$$

Based on the order sequence set S, the frequency of occurrence of any order combination in the log records can be counted.

It should be understood that, the number of combinations corresponding to any historical creation order also can be acquired based on the order sequence set S.

Since the order combination (commandᵢⱼ_{ᵢ}, commandᵢ₍ⱼ₊₁₎_{ᵢ}) is represented by one pair of corresponding creation orders (order_{f}, order_{g}) of BIM software, the frequency of occurrence of (order_{f}, order_{g}) in the order sequence set S is recorded as M_{fg}, and the number of order combinations with order_{f} as a first order therein is N_{f}.

Therefore, if the user uses order f at the moment Xₜ, the probability of using the creation order order_{g} by the user at the moment Xₜ₊₁ is:

p(f,g)=p(order_{f}→order_{g})=p(order_{g}|order_{f})=M_{fg}/N_{f}

The Markov chain transition probability matrix can be obtained:

$$P = [ \begin{matrix}\frac{{M}_{11}}{{N}_{1}} & \frac{{M}_{12}}{{N}_{1}} & … & \frac{{M}_{1 l}}{{N}_{1}} & … & \frac{{M}_{1 ( s - 1 )}}{{N}_{1}} & \frac{{M}_{1 s}}{{N}_{1}} \\ \frac{{M}_{21}}{{N}_{2}} & \frac{{M}_{22}}{{N}_{2}} & … & \frac{{M}_{2 l}}{{N}_{2}} & … & \frac{{M}_{2 ( s - 1 )}}{{N}_{2}} & \frac{{M}_{2 s}}{{N}_{2}} \\ … & … & … & … & … & … & … \\ \frac{{M}_{l 1}}{{N}_{l}} & \frac{{M}_{l 2}}{{N}_{l}} & … & \frac{{M}_{l l}}{{N}_{l}} & … & \frac{{M}_{l ( s - 1 )}}{{N}_{l}} & \frac{{M}_{l s}}{{N}_{l}} \\ … & … & … & … & … & … & … \\ \frac{{M}_{( s - 1 ) 1}}{{N}_{s - 1}} & \frac{{M}_{( s - 1 ) 2}}{{N}_{s - 1}} & … & \frac{{M}_{( s - 1 ) l}}{{N}_{s - 1}} & … & \frac{{M}_{( s - 1 ) ( s - 1 )}}{{N}_{s - 1}} & \frac{{M}_{( s - 1 ) s}}{{N}_{s - 1}} \\ \frac{{M}_{s 1}}{{N}_{s}} & \frac{{M}_{s 2}}{{N}_{s}} & … & \frac{{M}_{s 1}}{{N}_{s}} & … & \frac{{M}_{s ( s - 1 )}}{{N}_{s}} & \frac{{M}_{s s}}{{N}_{s}}\end{matrix} ]$$

It should be understood that in the above,

$$\frac{{M}_{f g}}{{N}_{f}} = p ( f , g )$$

In the above step of acquiring a log record of BIM component creation of the creator, the present embodiment provides a possible implementation mode, which may be realized in the following manner:

reading a log file in a designated path, acquiring a line text beginning with a specified character string in the log file, and generating a corresponding log record; in cases where the log record contains a first feature character string or does not contain a second feature character string, deleting the log record; and deleting a first line in the log record retained.

It should be understood that many operating systems and software applications have a method of recording a message, an error, an output, etc. in a file generally called as log file. The log file is used for diagnosing a problem or ensuring normal running of program. Such file also exists in the BIM software, and can be conveniently acquired from a default position of computer. The log file also contains relevant orders of BIM model operations and BIM component operations. In terms of collecting log files, in order to make data more representative, as many log files of the same user (creator) as possible can be collected, and the created transition probability matrix can improve the experience of individual users.

Taking BIM software being Autodesk Revit as an example for description, the log files can be acquired under a path “%LOCALAPPDATA%\Autodesk\Revit\<product name and version>\Journals”. For the present disclosure, a log file journal.xxxx.txt dedicated to the component creation is collected, wherein xxxx represents a number generated by the journal log file, and the log file under the path includes project operation log and component operation log. After finding a log file path (i.e., designated path) conforming to BIM software version, the user assigns the log file path to electronic equipment, and the electronic equipment acquires all files under the log file path, and screens out documents only in .txt format, then all the log files can be acquired.

Further, by acquiring the line text beginning with a specified character string in the log file, a corresponding log record can be generated.

Optionally, after all log files are read cyclically, in order to ensure integrity of original files, contents in the log files are read line by line in a read-only manner, and line texts beginning with “Jrn.Command” are screened out, including 6 classes of line texts beginning with “Jrn.Command” such as Jrn.CommandAccelKey, Jrn.CommandInternal, kn. Command StartupP age, kn. CommandRibb on, kn. C ommandKeyb oard Shortcut, and Jrn.CommandSystemMenu, where one “Jrn.Command” line represents one operation order.

It should be understood that, in the process of generating the log record, reading is performed according to a line arrangement sequence in the log file, so that the log record includes historical creation orders used by the creator in the process of creating the BIM component and the sequence of executing the historical creation orders. That is, the historical creation orders in the log record are arranged according to an execution sequence of UI.

In the above, the first feature character string is, for example, “Create new project”, and the second feature character string is, for example, “Create new family”. It should be noted that family is a specific term of the BIM component.

Optionally, the log file contains two types of logs, including project operation log and component operation log. After each log file is read, a corresponding log record can be generated.

By judging whether the log record contains the character string “Create new family” and does not contain the character string “Create new project”, the log record corresponding to the log file only for the BIM component creation is obtained, and so far m log records are acquired.

Optionally, in order to facilitate in creating the Markov transition probability matrix subsequently, part of the creation orders in the BIM software can be pre-processed.

It should be noted that, in all log records, the first line beginning with “Jrn.Command” in all log records is invalid content “Display or hide recently used files, ID_STARTUP_PAGE”. Therefore, this line needs to be deleted, to acquire an order line that only contains the component creation, and order name and order id in the line are further screened out. In turn, m log records are determined, and each log record contains nₘ component creation orders.

Based on the above, the BIM component creating method based on a recommended creation order provided in the present embodiment further may include the following step:

when any creation order other than the recommended creation order is determined as a new creation order, executing the new creation order, and updating the transition probability information.

Specifically, it may be continuously judged whether any recommended creation order is determined as the new creation order. When any recommended creation order is determined as the new creation order, it indicates that the user's use habit is matched with the current transition probability information, then the new creation order constituted by the recommended creation order is directly executed. When any creation order other than the recommended creation order is determined as the new creation order, it indicates that the user's use habit is not matched with the current transition probability information, then the determined new creation order other than the recommended creation order needs to be executed, and the transition probability information is updated.

It should be understood that, the updated transition probability information can better conform to the user's use habit, and helps to improve the user's creating efficiency.

Optionally, updating is completed based on a previous creation order and a new current creation order. Alternatively, after the determined new creation order other than the recommended creation order is executed, a log record corresponding to the log file is re-acquired, and updating of the transition probability information is completed.

After executing the new creation order in the above, the BIM component creating method based on a recommended creation order provided in the present embodiment further may include the following step:

determining whether the creation of the BIM component is completed, and if not, repeating the step of acquiring recommended creation orders based on a current creation order and transition probability information for creating a BIM component.

Optionally, it is determined whether the creation of the BIM component has been completed by judging whether the new creation order is an end marker, for example, rn.CommandSystemMenu. If not, the step of acquiring recommended creation orders based on a current creation order and transition probability information for creating a BIM component is repeated.

It should be noted that, the transition probability information in the embodiments of the present disclosure can be obtained in the above manner, and also can be directly downloaded from the electronic equipment, and can be dynamically updated in an operation process.

In a possible implementation mode, the electronic equipment can automatically recognize the version of the BIM software, so as to determine a designated path, to acquire a corresponding log file.

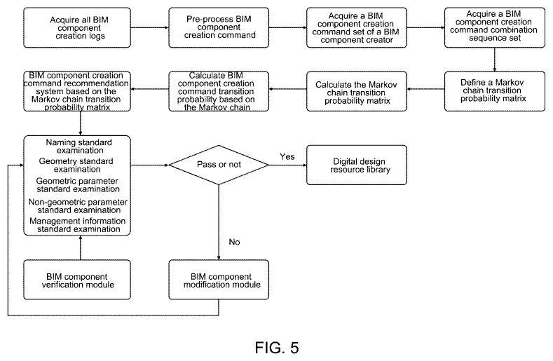

In order to more clearly recognize an overall process of the creating method in the present embodiment, the overall process in the present embodiment is shown in FIG. 5, and the overall process of the BIM component creating method based on a recommended creation order provided in the present embodiment is introduced below with reference to FIG. 5.

The BIM component creating method based on a recommended creation order may include 8 technical steps on the whole, including acquiring all BIM component creation logs, pre-processing BIM component creation command, acquiring a BIM component creation command set of a BIM component creator, acquiring a BIM component creation command combination sequence set, defining the Markov chain transition probability matrix, calculating the Markov chain transition probability matrix, calculating transition probability of BIM component creation command based on a Markov chain, and a recommendation system of BIM component creation command based on the Markov chain transition probability matrix.

After the BIM component is created, it enters a checking procedure, to complete naming standard examination, geometry standard examination, geometric parameter standard examination, non-geometric parameter standard examination, and management information standard examination. In the geometric parameter standard examination, the BIM component verification module can be used to assist the examination; the BIM component passing the examination is directly stored in a library, the BIM component failing to pass the examination is further modified by the BIM component modification module, and the modified BIM component continues to be examined.

In the present embodiment, for an implementation mode of how to acquire all BIM component creation logs to calculate transition probability of BIM component creation command based on a Markov chain, reference can be made to relevant description in the above embodiments, which is not repeated herein. On this basis, a BIM component creation command recommendation system based on the Markov chain transition probability matrix is developed using BIM software secondary development, and this system can automatically recommend to the user the commands that may be executed next in the process of creating the BIM component in the BIM software.

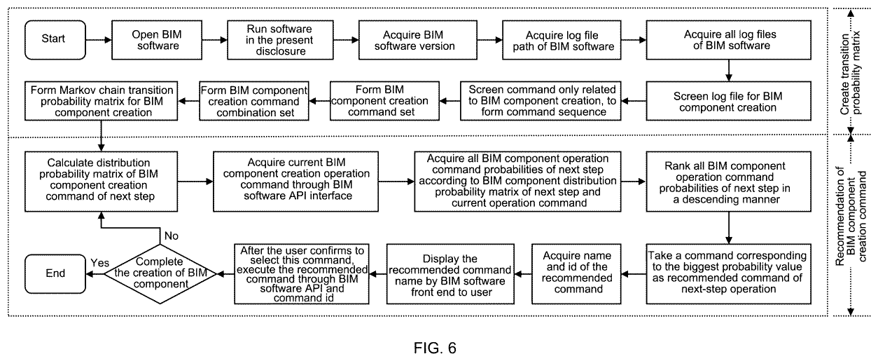

Referring to what is shown in FIG. 6, an overall operation process of the BIM component creation command recommendation system based on the Markov chain mainly includes two parts: creating the transition probability matrix and recommendating BIM component creation command.

During implementation, the user needs to install the system into the BIM software, and when started for the first time, the system will automatically acquire the current BIM software version through VersionName attribute in Revit Application object, and automatically form all log files under the path “%LOCALAPPDATA%\Autodesk\Revit\<product name and version>\Journals” for accessing log files, and screen out log files only for creating the BIM component, and cyclically acquire command lines only related to creating the BIM component in all log files, and after pre-processing, form a set of all commands commonly used in the process of creating the BIM component by the user, and a BIM component operation command combination sequence. Then, frequency of occurrence of each command combination sequence, and the number of command sequences with the same command as the first state are counted, and the probability of transferring each command to other commands is calculated by relative proportion, to form the transition probability matrix, and finally form the transition probability matrix with the user's own data as a starting point.

In the part of BIM component creation command recommendation, the system may automatically calculate the transition probability matrix (distribution probability matrix) P of the next step according to the existing transition probability matrix P. The system acquires a current BIM component creation operation command name input by the user via a BIM software API, automatically matches the command order_{f} in a command set Q and number f thereof, and acquires a probability matrix P(f) of order_{f} in the transition probability matrix P according to the matched number. A command orderⱼ corresponding to the maximum probability value in P(f) is further acquired, which is the name of the command to be executed in the next step. The id of the command orderⱼ is correspondingly acquired, and when the user selects to accept the recommendation result, the user select the command of corresponding id via the BIM software API to execute.

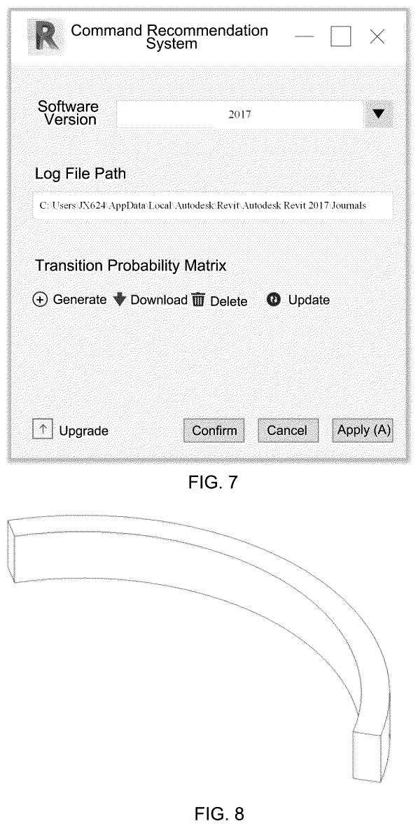

In the present embodiment, the recommendation system is installed in the form of BIM software, and after being installed, can automatically identify the software version and existing BIM component creation log of the corresponding version, generate an operation command transition probability matrix, also can download, delete, and update the operation command transition probability matrix, and initiatively update the software. As shown in FIG. 7 and FIG. 8, a setting and operation interface of the BIM component creation command recommendation system based on the Markov chain, and use effect of the BIM component creation command recommendation system based on the Markov chain in the present embodiment are shown respectively.

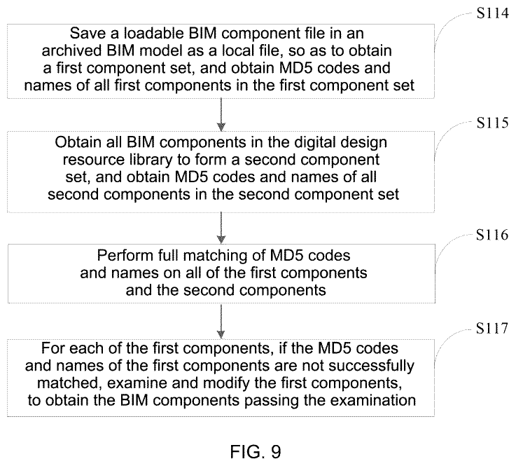

It can be seen from the above that, in the digital design resource library application method, the BIM component also can be created by a BIM component creating method of automatic extraction by BIM model. Referring to FIG. 9, in the digital design resource library application method provided in an embodiment of the present disclosure, the BIM component creation based on automatic extraction by BIM model can be realized in the following manner:

S114, saving a loadable BIM component file in an archived BIM model as a local file, so as to obtain a first component set, and obtaining MD5 codes and names of all first components in the first component set;

S115, obtaining all BIM components in the digital design resource library to form a second component set, and obtaining MD5 codes and names of all second components in the second component set;

S116, performing full matching on MD5 codes and names on all of the first components and the second components; and

S117, for each of the first components, if the MD5 codes and names of the first components are not successfully matched, examining and modifying the first components, to obtain the BIM components passing the examination.

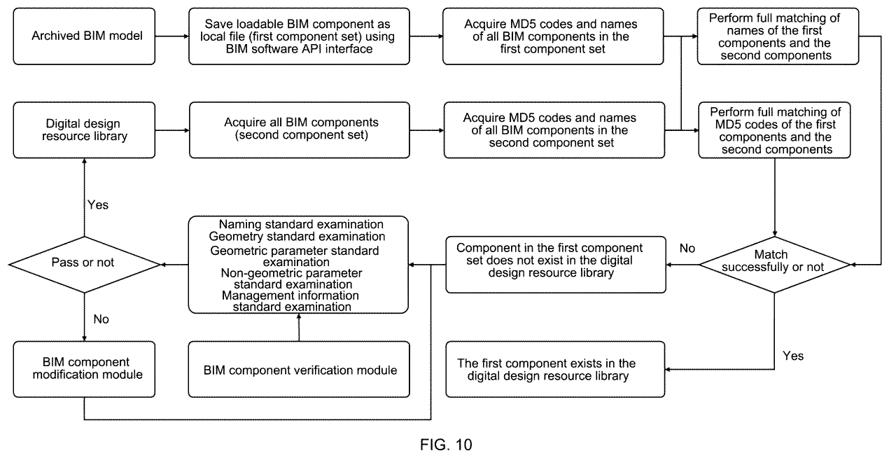

Referring to FIG. 10, in the present embodiment, the loadable BIM components in the archived BIM model are acquired using the API interface of the BIM software. The archived BIM model refers to a BIM model that is archived after collaborative design is finished, and this BIM model is a generation basis of a final blueprint and design delivery basis.

In the present embodiment, saving the loadable BIM components as a local file using the API interface of the BIM software can be realized in the following manner:

1) creating an Autodesk Cloud Transmitter service, and enabling license check of an external application;

2) opening a Revit document to be processed by an OpenDocumentFile( ) method;

3) acquiring all loadable BIM components in the document using FilteredElementCollector class;

4) traversing all elements in the loadable BIM components, and converting the same to Family objects; and

5) storing the BIM component file locally using SaveAs function of the Family objects, to obtain in a local file.

The MD5 code, as an encryption algorithm, is a widely used cryptographic hash function, and can generate a 128-bit (16-byte) hash value, for ensuring integrity and consistency of information transmission, and meanwhile, the MD5 code has uniqueness. Since the BIM components have characteristics such as a large number and great change, taking the component name and the component file MD5 code as comparison features of the first component and the second component, the situation of repeatedly creating components of the same class can be effectively avoided. In the above, the component name follows a standardized naming manner, and the MD5 code can prevent the user from only modifying the component name and creating it repeatedly on the basis of the BIM component encryption. The MD5 code is unique code of a BIM model component file, and herein serves as a unique code of a BIM component file.

In a possible implementation mode, the BIM component creating mode based on automatic extraction by BIM model in the present embodiment further may include the following steps:

if one of the MD5 code and name of the first component being successfully matched with that of any second component, the second component being a component of the same type as the first component; and acquiring a parameter set and a sum formula database of the component of the same type, and binding the parameter set and the sum formula database with the first component, so as to write the parameter set and the sum formula database into the first component.

In the present embodiment, if the first component is found to be a specific component after the first component is compared with the second component, that is, one of the MD5 code and name of the first component can be successfully matched with that of the second component, it indicates that there is no such component in the existing digital design resource library, but a component of the same type exists, i.e., the matched second component. Therefore, the parameter set and the sum formula database of the second component of the same type as the specific component in the digital design resource library can be written in the specific component.

In the present embodiment, in a possible implementation mode, the writing of the parameter set and the sum formula database can be completed in the following manner:

importing a namespace library in the BIM software; reading binary data of the BIM component file including components of the same type, the binary data including the parameter set and the sum formula database of the components of the same type; calculating an MD5 code of the binary data; and outputting the name of the BIM component file and the corresponding MD5 code into a text file or database of the first component.

In the present embodiment, an System.Security.Cryptography namespace library is imported so as to use an MD5 calculation method. The file containing components of the same type exists in the digital design resource library in the form of BIM component file. By performing the MD5 code calculation on the parameter set and the sum formula database of components of the same type, the name and the corresponding MD5 code of the BIM component file thereof are output to the text file or the database of the first component, to serve as a record set, thereby realizing successful write-in.

In the present embodiment, in the above, for the first component whose MD5 code and name neither can be matched with that of the second component in the digital design resource library, the first component is examined and modified, and the first component passing the examination can be taken as a created BIM component, and stored in the digital design resource library. For the first component that fails to pass the examination, the first component can be further modified by the BIM component modification module, and the modified first component is examined again.

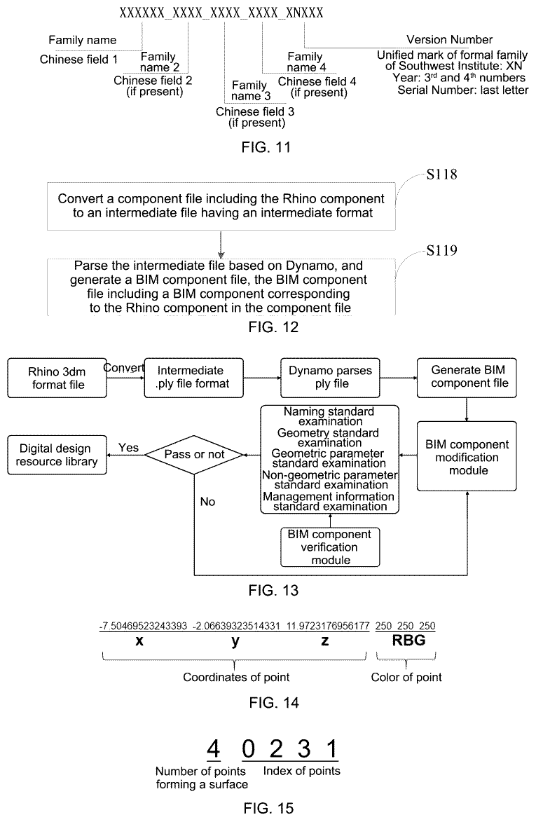

When examining the first component, the BIM component verification module can be used to assist the examination, and the naming standard examination, geometry standard examination, geometric parameter standard examination, non-geometric parameter standard examination, and management information standard examination can be completed based on a digital design resource construction standard. In the above, the naming standard examination can be performed in accordance with a BIM component naming standard as shown in FIG. 11. The geometry standard requires authenticity of geometry of the component. The geometric parameter standard requires that the geometry can be parametrization-driven. The non-geometric parameter standard requires that the design expression and multi-specialty coordination need can be satisfied. The management information standard requires that relevant requirements of digital design resource management can be met.

The above is for the BIM component creating mode based on automatic extraction by BIM model, and it can be seen from the above that in the digital design resource library application method, the BIM component also can be created in the BIM component creating mode based on Rhino component conversion.

Referring to FIG. 12, in the present embodiment, in a possible implementation mode, the BIM component creation can be performed based on the Rhino component conversion in the following manner:

S118, converting a component file including the Rhino component to an intermediate file having an intermediate format; and

S119, parsing the intermediate file based on Dynamo, and generating a BIM component file, wherein the BIM component file includes a BIM component corresponding to the Rhino component in the component file.

In the present embodiment, referring to FIG. 13, the file format of the component file of the Rhino component is .3dm format, the file format of the intermediate file is .ply format, and further, the ply format file is parsed using Dynamo, so as to generate a BIM component having only geometry.

On this basis, the BIM component only having the geometry further can be modified using the BIM component modification module, subsequently, the BIM component is created, it enters a checking procedure, to complete naming standard examination, geometry standard examination, geometric parameter standard examination, non-geometric parameter standard examination, and management information standard examination. In the geometric parameter standard examination, the BIM component verification module can be used to assist the examination. The BIM component passing the examination is directly stored, the BIM component failing to pass the examination is further modified by the BIM component modification module, and the modified BIM component continues to be examined.

In the present embodiment, firstly, rhino is opened, to convert the 3dm format to the ply format, and then the ply format is converted to the rfa format in the dynamo of the BIM software Revit.

In the present embodiment, in a possible implementation mode, the step of converting the component file including the Rhino component to an intermediate file having an intermediate format can be realized in the following manner:

acquiring all component files according to an acquired folder path saving the component file including the Rhino component, and saving the same in a file list; and capturing the Rhino component in the component file from the file list by means of a selection command, converting a format of the Rhino component to the intermediate format, and storing the converted component in the obtained folder path for storing the intermediate file.

In the present embodiment, it is necessary to use an intermediate format to convert the 3dm file to the rfa file. It is very difficult for Revit to directly parse a 3dm file, and it is necessary to introduce an intermediate format, wherein this format is required to be universal enough and capable of being used for various models, and has strong readability to facilitate parsing a file, and the ply file format satisfies the two requirements very well.

The ply format is a commonly used format in computer graphics. A typical ply object definition is a (x,y,z) triplet list of a vertex and a face list described by an index in the vertex list. The vertex and the face together with some supplementary attributes (normal, color, etc.) can sufficiently describe a three-dimensional shape of a model, and therefore the ply file can be applied to three-dimensional models in various shapes, and remains generic in models. Meanwhile, the ply file has strong readability. File formats have two versions, one is ASCII, and the other is binary. The two formats both can be read through document, first three numbers are X, Y, and Z values of a point respectively, and last three numbers represent RBG value of this point. An index of a group of points is used to represent a surface, as shown in FIG. 14.

In the document, a line formed by six numbers represents a point, as shown in FIG. 15. The first number represents the number of vertexes forming a surface, and the following numbers represent an index of the vertexes on the surface. Complex models are all composed of many points and surfaces, and coordinates and vertices thereof can be easily extracted. Therefore, the ply file has strong readability.

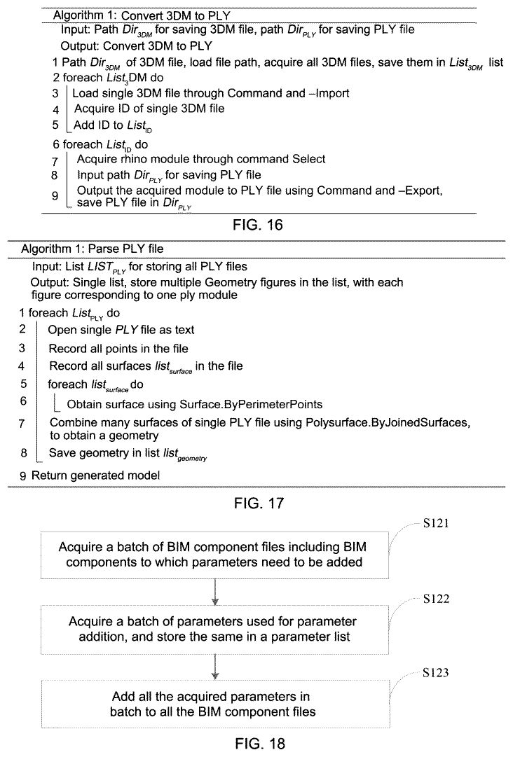

FIG. 16 schematically shows implementation codes of an algorithm for converting the 3dm format file to the ply format file. On this basis, a designer only needs to input a path for saving the 3dm file and a path for saving the ply file, then the program will load a model according to the algorithm, and convert the model format. For example, a path for saving the 3dm file is input at importedObjs=import_3dm(“.\\3dm_path”,“3dm”), and a path desired to save the ply file having completed the format conversion is input at export_ply (importedObjs,“.\\ply_save”,“ply”), and when “Run” is clicked, the program will automatically convert the 3dm format files to the ply format files in batch.

After the ply format file is obtained, the 3dm file can be converted to the rfa format file (BIM component file) through the ply intermediate format, and the file conversion is realized through the dynamo built in the Revit. In a possible implementation mode, the BIM component file can be generated by parsing the intermediate file based on the Dynamo in the following manner:

based on a code block in the Dynamo, after acquiring all intermediate files, recording points and surfaces of the components in each intermediate file; traversing the surfaces in the intermediate files, combining all the surfaces to obtain a geometry, and storing the geometry in the geometry list; and creating a blank BIM component template file, and generating a BIM component file based on the geometry list saving the geometry and the BIM component template file.

In the present embodiment, in acquiring the code block of the intermediate file, a Directory Path code block in the system is called first, to acquire a folder path for storing the ply file, next the folder path is transferred to a custom code block, with input and output being unchanged, and transferred to a Directory From Path code block of the system, a directory is acquired from the path, and then a result is put in FileSystem.GetDirectoryContents. All ply folder paths in the directory are acquired, and output in the form of a three-layer dictionary, and finally the three-layer dictionary is changed into one layer. By clicking “Browse”, one system folder window is opened, all ply files that need to be converted can be acquired by clicking. After the ply files are acquired, they need to be parsed for generating a model in the Revit.

In the code block parsing the intermediate file in the Dynamo, ImportInstance.ByGeometry code block in the Dynamo system is used to view a generation result of the model. An implementation algorithm code of the code block parsing the file is as shown in FIG. 17.

After the file is parsed, the BIM component needs to be created. In the present embodiment, in the code block creating the BIM component, the code block creating the BIM component is transferred to a blank BIM component template file, and type and name of the BIM component, and a result generated by a previous code block are stored in a list, then the BIM component can be generated through familyInstance.ByGeometry.

On this basis, the BIM component file is saved. When saving the BIM component file, a BIM component list in creating the BIM component, and a saving path and a saving name of the BIM component need to be input. To save the BIM component, the current Revit file is acquired first, the newly created BIM component is acquired from the Revit file, and then the BIM component is saved in the input path. Finally, the file whose format is converted from the 3dm format to the ply format and then to the rfa format can be obtained.

On the basis of the above design, in implementation, the designer only needs to input the path for loading the 3dm format file in the process of converting the 3dm format to the ply format, and save the path of the ply format file; and in the process of converting the ply file to the rfa, the designer only needs to click the path for loading the ply file, save the path of the rfa file, and save the rfa file name, then the Rhino component can be converted to the BIM component.

The creating modes of the BIM component in the present embodiment are introduced in the above, and in implementation, the BIM component can be created in any one or more of the above creating modes.

Based on the above, for the created BIM component or an original BIM component in the digital design resource library, there is a component to which parameters need to be added. In order to meet requirements of enterprises, when adding parameters to the BIM components, the worker needs to open individual components in sequence to operate. However, a large number of BIM components are often stored in the digital design resource library, and the efficiency of adding parameters in the above manner is low. If a plurality of BIM component files can be acquired at one time, and a batch operation is performed on the plurality of BIM component files, the efficiency of operating the BIM component parameters by the operator can be significantly improved.

Based on this, in the present embodiment, an implementation mode in which parameters can be added in batch is provided. Referring to FIG. 18, when performing batch addition of parameters to the BIM components in the present embodiment, it can be realized in the following manner:

S121, acquiring a batch of BIM component files including BIM components to which parameters need to be added;

S122, acquiring a batch of parameters used for parameter addition, and storing the same in a parameter list; and

S123, adding all the acquired parameters in batch to all the BIM component files.

It should be noted that, the sequence of executing the above step S121 and step S122 is not limited.

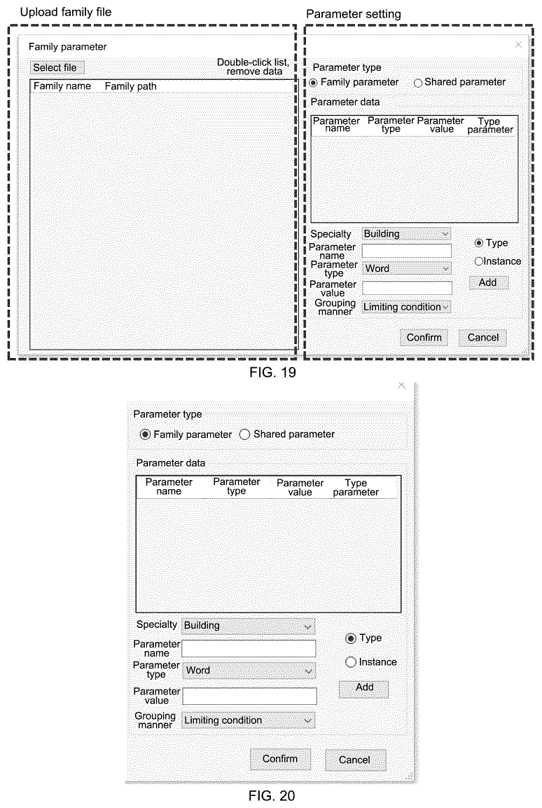

In the present embodiment, the above functions can be realized by a plug-in developed in the BIM software, a front-end interface of the plug-in can be as shown in FIG. 19, and this interface consists of two parts, including family file loading and parameter setting. It should be noted that the family mentioned in the present disclosure can be understood as BIM component, and the “family” is a subordinate concept of the BIM component.

In order to realize the function of acquiring the BIM component files in batch, the BIM component files need to be added first, and in the present embodiment, it can be realized in the following manner.

1) calling OpenFileDialog class of C#. Instantiating this class can realize that a file dialog box is popped up by clicking a button. In specific class instantiation, attributes are set for the OpenFileDialog class, wherein key attributes include: setting Multiselect attribute to be true, so as to realize a function of selecting multiple files, and setting Filter attribute to be “BIM component file (*.rfar)|*.rfa”, so as to realize that the selected file must be a BIM component file.

2) setting a list, wherein name of the list can be files, and storing a path of the BIM component file acquired in step 1).

3) calling DataGridViewTextBoxCell class of C#. By instantiating this class, the BIM component file acquired through the OpenFileDialog class in step 1) can be viewed in the plug-in interface. In specific class instantiation, a file name of the BIM component is first assigned to Value attribute of DataGridViewTextBoxCell, and a character string of a folder where the file is located is also assigned to the Value attribute of DataGridViewTextBoxCell. Then the file name of the BIM component and the name of the folder where the file name of the BIM component is located are displayed in the interface through the following function:

DataGridViewTextBoxCell.Cells.Add( ).

Through the above three steps, a “Select file” button in the plug-in interface can be clicked, so as to open the folder of the selected BIM component file, after a plurality of BIM component files are selected, BIM component file information is stored in the files list at rear end, and the selected BIM component file can be seen in the plug-in interface.

In the above situation of acquiring a batch of BIM component files, as enterprises often have a plurality of BIM component files requiring operating parameters, in order to avoid the worker from re-selecting the BIM component files in batch due to the existence of a minority of BIM component files that do not need to be modified in the BIM component files selected in batch, a function of removing a BIM component file needs to be added to a module for acquiring the BIM component files in batch.

When the BIM component files are selected in batch, as the number of BIM component files is large, it is often necessary to acquire all the BIM component files that need to be modified in several batches. In the selection of several batches, the worker is prone to selecting repeated BIM component files. In order to avoid repeatedly adding parameters to the same BIM component file, further judgment is required.

Moreover, a premise of adding parameters to the BIM component file in the BIM software, such as Revit, in the current electronic equipment is that the BIM component file needs to be openable in the Revit, and when the version of the BIM component file is higher than the Revit, the worker cannot open the BIM component file, and thus cannot add the parameters. Therefore, when the BIM component files are acquired in batch, in the present embodiment, it is also necessary to ensure that the BIM component files are openable in the Revit.

Based on this, in the present embodiment, the step of performing batch addition of parameters to the BIM component, it further may include the following steps:

eliminating repeated BIM component files among all the acquired BIM component files; and eliminating a BIM component file of which version information is higher than current version information of the BIM software.

In the present embodiment, when judging whether there are repeated BIM component files among all the BIM component files, it may be realized in the following manner.

In the present embodiment, after a plurality of BIM component files are acquired through the OpenFileDialog class in the above, names of the BIM component files and a folder path where the BIM component files are located are extracted, and then they are judged with names of the BIM component files that are already stored in DataGridViewTextBoxCell and the path where the BIM component files are located. A specific judging rule is as follows: judging whether the acquired BIM component file names and the folder path where the BIM component files are located are completely the same as those stored in the DataGridViewTextBoxCell, if so, it indicates that the current BIM component files are repeated, otherwise, it indicates being not repeated, and the acquired BIM component files are added to the flies list, and displayed in the plug-in interface.

In order to realize the function of removing the BIM component file, the BIM component file can be displayed in WinForm with a double-click event on the line character, and when the worker double-clicks the BIM component file that needs to be removed on the interface, the corresponding BIM component file can be removed from the interface. At the same time, the name of the double-clicked BIM component file is found in the storage list files to which the BIM component file is added, and removed.

The step of eliminating a BIM component file of which version information is higher than current version information of the BIM software may be realized in the following manner:

acquiring version information of each to-be-added BIM component file and current version information of the BIM software; determining whether the version information of the to-be-added BIM component file is higher than the current version information of the BIM software; if so, eliminating a BIM component file of which version information is higher than the current version information of the BIM software; and if not, retaining the same.

In the present embodiment, the BIM component file is opened by means of a file stream FileStream, a byte array of the BIM component file is acquired, and then the byte array is converted to String by means of Unicode coding. For a BIM component file of 2018 version, a character string of 2018 exists in a conversion result, for a BIM component file of 2019 version, a character string of 2019 exists in a conversion result, and for a BIM component file of a corresponding version Revit version, a character string corresponding to a corresponding version also exists in a conversion result. Therefore, it is possible to view whether there is a corresponding character string in a manner of regular matching, so as to acquire the version of the BIM component file.

When the version information of the current Revit is acquired, the following function can be called from Revit package to acquire the version information of the current Revit program:

Document.Application.VersionNumber.

When it is judged whether the version information of the BIM component file is higher than the version information of the current Revit, the version information of the BIM component file acquired in a first step is compared with Revit version information acquired in a second step in sequence, and if the version of the BIM component file is higher than the Revit version, it is not added to the files list for storage, or displayed in the plug-in interface.

In addition, after the BIM component file to which parameters need to be added in batch, the worker can set a plurality of parameters, and add the plurality of parameters in batch to the plurality of BIM component files.

First, parameter types of the parameters involved in the present embodiment are described. The parameters can be classified into family parameter and shared parameter. In the above, the family parameter controls variable values of a family, e.g., dimension or material. The family parameter is specific to a current family. The shared parameter is a parameter that can be used in a plurality of BIM components and projects, and after a definition of shared parameter is added to a BIM component or project, it can be used as parameter of the BIM component or project. The shared parameter is defined in a shared parameter file (.txt) outside of the Revit, and therefore can be prevented from being changed.

Besides, the parameters also can be divided into type parameter and instance parameter, wherein the type parameter is a parameter defining BIM component type. Once a value of the type parameter is modified, parameter value of all type individuals, i.e., BIM component instances, change accordingly. When a parameter value of one BIM component instance of the same BIM component type is changed, parameter values of other BIM component instances are changed accordingly. Instance parameter is a parameter that defines a BIM component instance. When a parameter value of a BIM component instance is changed, values of other BIM component instances of the same BIM component type do not change.

During implementation, parameters need to be added to the BIM component, and information that needs to be used includes: specialty, parameter name, parameter type, parameter value, and grouping manner. In the above, the specialty includes building specialty, structure specialty, water supply and drainage specialty, heating and ventilation specialty, and electric specialty. The parameter name is a character string. The parameter type needs to consider the specialty corresponding to the parameter. The grouping manner includes limiting condition, word, dimension standard, identification data, and others.

In the present embodiment, considering the parameter types and corresponding specialties frequently processed by enterprises, the specialties and the corresponding parameter types as shown in Table 2 are sorted out.

TABLE 2
Specialties and Corresponding Parameter Types

| Specialty | Parameter type |
|---|---|
| Building | Word, multi-line words, yes/no, length, integer, number, angle, |
| specialty | material, area, speed |
| Structure | Word |
| specialty | |
| Water supply and | Word, multi-line words, flow rate, head, power, dead weight, |
| drainage | operating weight, effective volume, heat capacity, hot water |
| | output, total volume, water storage volume, heat transfer area |
| Heating and | Air volume, power, speed, word, length |
| ventilation | |
| specialty | |
| Electric specialty | Word, multi-line words, yes/no, length, integer, value, material, |
| | area, voltage, current, power, apparent power, frequency, |
| | illuminance, brightness, luminous flux, luminous intensity, color |
| | temperature, demand system, number of poles, load classification |

In the present embodiment, when the plug-in acquires the parameter information, a parameter acquisition interface needs to be set. As adding one parameter to one BIM component needs the information including, for example, specialty, parameter name, parameter type, parameter value, and grouping manner, one acquisition interface needs to be set for each piece of information, specifically in a setting mode as follows:

specialty: instantiating ComboBox class of C#, and setting a dropdown list control, with dropdown options including: building, structure, water supply and drainage, heating and ventilation, and electrics;

parameter name: instantiating TextBox class of C#, and setting a text edit box;

parameter type: setting an interface style of the parameter type, wherein a current specialty needs to be judged first, then the ComboBox class of C# is called for instantiation, and dropdown options set are as shown in the table;

parameter value: instantiating the TextBox class of C#, and setting a text edit box; and

grouping manner: instantiating the ComboBox class of C#, and setting a dropdown list control, options of the control including: limiting condition, text, dimension standard, identification data, and others.

On this basis, it is necessary to determine whether the parameter is a type parameter or an instance parameter.

With regard to the same parameter information, setting a parameter as a type parameter will have an influence on all BIM component instances of the same type, setting a parameter as an instance parameter only has an influence on the current BIM component instance, and when a parameter is added to the BIM component, the category of the parameter needs to be determined.

A button is provided in the plug-in interface for selection, and is realized by instantiating RadioButton, and then the worker can determine whether a current parameter is a type parameter or an instance parameter.

In addition, it needs to determine whether a parameter is a family parameter or a shared parameter. A button is set in the plug-in interface to select the category of the parameter: shared parameter or family parameter, which is realized by instantiating RadioButton. A parameter information interface of the plug-in is as shown in FIG. 20.

Besides, a manner of storing the parameter needs to be set. As each parameter has the information including: family parameter/shared parameter, type parameter/instance parameter, specialty, parameter name, parameter type, parameter value, and grouping manner, a single parameter can be stored according to the class.

In the present embodiment, a FamilyParamInfo class is declared in C#, and the following attributes are added to this class: ParamName of string type, indicating name of a parameter; IsShareParam of bool type, indicating whether the current parameter is a family parameter or a shared parameter; Islnstance of bool type, indicating whether the current parameter is a type parameter or an instance parameter; ParamType of string type, indicating the parameter type, ParamValue of string type, indicating the parameter value, and GroupType of string type, indicating the grouping manner. A plurality of parameters are stored by one list.

Based on the above, in the present embodiment, batch parameters can be added to batch BIM component files in the following manner:

determining one target BIM component file from all BIM component files to be added with parameters, wherein the target BIM component file includes at least one BIM component; in cases where the parameter list further includes any parameter in a to-be-added state, selecting one parameter in the to-be-added state as a target parameter; in cases where there is no target parameter in the target BIM component file, adding the target parameter to the target BIM component file, and modifying the target parameter to be in an added state; determining whether the parameter list further includes a parameter in the to-be-added state; if the parameter in the to-be-added state being further included, repeatedly selecting one parameter in the to-be-added state as the target parameter, until all parameters in the parameter list are in the added state; if all the parameters in the parameter list being in the added state, modifying the target BIM component file to be in the added state; determining whether there is still a BIM component file to be added with parameters; and if so, modifying all the parameters in the parameter list into the to-be-added state, and repeatedly determining one target BIM component file from the BIM component files to be added with parameters, until all the BIM component files complete the parameter addition.

In the present embodiment, after all the BIM component files and all the parameters are acquired, the BIM component files and the parameters are all stored in the form of a list. In the present embodiment, each BIM component file is traversed by a cycle, and parameters are added in sequence for each BIM component file through For cycle.

Since the family parameter and the shared parameter are greatly different not only in use effect, but also greatly different when the automatic addition of parameters to the component is realized, the family parameter addition and the shared parameter addition need to be realized separately. Based on this, in the present embodiment, when the target parameter is added to the target BIM component file, it can be realized in the following manner:

mapping the target parameter based on a preset mapping function, so as to obtain a mapping value; determining the target parameter as a shared parameter or a family parameter; when the target parameter is a shared parameter, adding the mapping value to the target BIM component file based on a shared parameter function; and when the target parameter is a family parameter, adding the mapping value to the target BIM component file based on a family parameter function.

Since the acquired parameter information is a character string expressed in words, and needs to be replaced with different Int type integers in Reivt secondary development, a mapping function needs to be established.

In the present embodiment, the parameter types acquired at the front end are all represented by Chinese character strings such as “word”, “integer”, “angle”, and “length”, and all parameter types need to be converted to Int type integers in the Revit secondary development. For example, when an input parameter type is integer, the mapping function outputs integer 2; and when an input parameter type is angle, the mapping function outputs integer 7. For a specific mapping rule, reference can be made to a Revit API.

The grouping types acquired at the front end are all identified by Chinese characters such as “limiting condition”, “word”, “dimension marking” and “identification data”, and all the grouping types need to be converted to values of the Int type in the Revit secondary development. For example, when a grouping type is limiting condition, the mapping function outputs integer −5000119; and when a grouping type is word, the mapping function outputs integer −5000123.

In the present embodiment, the function for adding the family parameter can be established in the following manner:

1) opening a BIM component file using a function Document.Application.OpenDocumentFile( );

2) acquiring FamilyManager class of the BIM component file;

3) acquiring parameter type mapping and grouping type mapping of the parameter by means of a mapping function; and

4) calling a function FamilyManager.AddParameter( ), inputting a parameter name, grouping manner mapping, a parameter type, and a bool value of instance parameter or shared parameter, and realizing addition of the parameter to the BIM component file.

In the present embodiment, the function for adding the shared parameter further can be established in the following manner:

1) opening a BIM component file using a function Document.Application.OpenDocumentFile( );

2) acquiring FamilyManager class of the BIM component file;

3) creating a new file of shared parameter, and assigning the new shared parameter file to the BIM component file by calling the following attribute:

Document.Application.SharedParametersFilename attribute;

4) calling a function Document.Application.OpenSharedParameterFile( ), and opening the shared parameter file;

5) creating a new shared parameter group for this shared parameter file: calling a function DefinitionFile.Groups.Create( ) for realization;

6) instantiating ExternalDefinitionCreationOptions class, putting a parameter name and a parameter type into the class, and converting the same into ExternalDefinition; and

7) calling a function FamilyManager.AddParameter( ), and transmitting a result of step 6), a parameter grouping manner, and whether being an instance parameter to the function, to realize addition of the shared parameter to the BIM component file.

In the present embodiment, a function of parameter assignment can be established in the following manner:

1) judging whether a parameter value is dimension, and if so, converting the same to foot; and

2) calling a function FamilyManager.Set( ), to assign a value to the parameter.

In addition, in the implementation process, before adding the parameter to the BIM component file, it also needs to judge whether the parameter already exists in the BIM component file. In the present embodiment, in the step of adding all the parameters to all the BIM component files in batch, whether the parameters are repeated also can be judged in the following manner:

acquiring parameter names of all existing parameters in the target BIM component file; determining whether the parameter name of the target parameter is the same as the parameter name of any existing parameter in the target BIM component file; if so, determining that the target parameter exists in the target BIM component file; in cases where the target parameter exists in the target BIM component file, modifying the target parameter to be in the added state; and if not, determining that there is no target parameter in the target BIM component file.

In the present embodiment, in specific implementation, a relevant function for judging whether a parameter exists can be established to execute a judging process, and specifically, an implementation form is as follows:

1) opening a BIM component file using the function Document.Application.OpenDocumentFile( );

2) acquiring FamilyManager class of the BIM component file;

3) acquiring all parameters FamilyParameterSet existing in the BIM component from the FamilyManager class of the BIM component; and

4) traversing the FamilyParameterSet, and checking whether each existing parameter appears in the list of parameters that need to be added, wherein if so, it indicates that the newly added parameter already exists in the BIM component file, and if not, it indicates that the newly added parameter does not exist in the BIM component file.

The process of creating a BIM component based on a plurality of creating modes and realizing the batch addition of parameters to batch BIM components has been described in the above. In addition, referring again to FIG. 2, when modifying the parameter of the BIM component, in addition to setting the parameter of the BIM component by the BIM component modification module in the above manner, the parameter of the BIM component also can be added/deleted manually.

In the prior art, there lacks an effective verification method for a created BIM component, and in particular, there is the problem of low efficiency in the verification of the parameterization capability of the BIM component.

Based on this, in the present embodiment, on the basis of the above, after the creator performs geometric parameter binding on the BIM component to which the parameters are added, geometric parameter visualization verification can be performed on the BIM component, so as to solve the above problems targetedly.

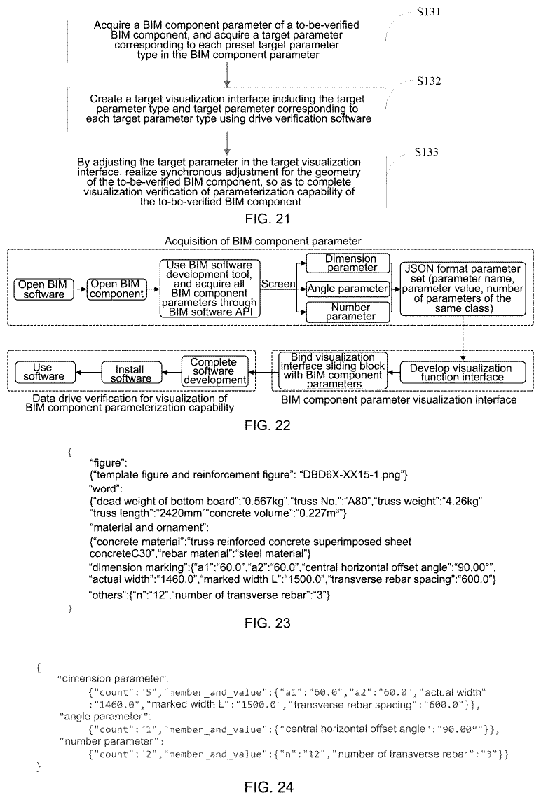

Referring to FIG. 21, in the present embodiment, the geometric parameter visualization verification on the BIM component can be performed in the following manner.

S131, acquiring a BIM component parameter of a to-be-verified BIM component, and acquiring a target parameter corresponding to each preset target parameter type in the BIM component parameter.

S132, creating a target visualization interface including the target parameter type and target parameter corresponding to each target parameter type using drive verification software.

In the above, the target visualization interface is located above the to-be-verified BIM component corresponding to the BIM component parameter, and geometry of the to-be-verified BIM component can be synchronously adjusted with the adjustment of the target parameter.

S133, by adjusting the target parameter in the target visualization interface, realizing synchronous adjustment of the geometry of the to-be-verified BIM component, so as to complete visualization verification of parameterization capability of the to-be-verified BIM component.

In the present embodiment, the visualization verification of the geometric parameter of the BIM component can be realized by the BIM component verification module. Referring to FIG. 22, the implementation of the BIM component verification module may mainly include three parts, i.e., BIM component parameter acquisition, visualization interface for BIM component parameter, and visualization data drive verification for BIM component parameterization capability.

In the present embodiment, firstly, the BIM component parameter of the to-be-verified BIM component is acquire in the following manner:

installing and opening the developed drive verification software in the BIM software; and opening the to-be-verified BIM component, and acquiring the BIM component parameter of the to-be-verified BIM component using the drive verification software.

In the present embodiment, after the BIM software opens the BIM component file based on the drive verification software, relevant API interface of the BIM software is used, to acquire all the BIM component parameters, form a JSON (JavaScript Object Notation) format parameter set; filter and screen out three classes of parameters, i.e., the dimension parameter, the angle parameter, and the number parameter, from the parameter set, containing the parameter name, the parameter value, and the number of parameters of the same class; transmit and use the same in a JSON data format; and finally realize the transmission of the BIM component parameter in a standardized format.

In the above, the dimension parameter refers to dimension annotation having a binding relationship with the geometry of the BIM component, and is bound to a parameter tag, can drive the geometry of the BIM component to dynamically change by modifying the dimension annotation or the parameter tag, including metric unit and British unit; the angle parameter refers to angle annotation having a relationship with the BIM component geometry, and is bound to the parameter tag, and can drive the geometry of the BIM component to dynamically change by modifying the angle annotation or the parameter tag, with a common unit of degree; the number parameter refers to number annotation having a binding relationship with the geometry of the BIM component, is bound to the parameter tag, and can drive the geometry of the BIM component to dynamically change by modifying the number annotation or the parameter tag.

The BIM software is not directed to specific software, and relevant BIM modelling software capable of satisfying the BIM concept is applicable. Although using methods of API interfaces of different BIM software are different, a parameter set can be formed by acquiring all parameters in the BIM component, and three classes of parameters, i.e., the dimension parameter, the angle parameter, and the number parameter, containing the parameter name, the parameter value, and the number of parameters of the same class, are screened out from the parameter set. The screening manner is different according to different IBM software API, and the parameters are finally transmitted in the program in the form of a JSON dataset.

For example, three classes of parameters of the BIM component, i.e., the dimension parameter, the angle parameter, and the number parameter, are acquired, containing the parameter name, the parameter value, and the number of parameters of the same class, and a parameter set is as shown in FIG. 23, wherein two parameters, i.e., “actual span” and “marked span”, are calculated and defined by other parameters, without the need of being taken out.

The three classes of parameters, i.e., the dimension parameter, the angle parameter, and the number parameter, are filtered and screened out from the parameter set, containing the parameter name, the parameter value, the number of parameters of the same class, and a JSON format dataset is formed. This step is used for dynamically generating variables, as shown in FIG. 24.

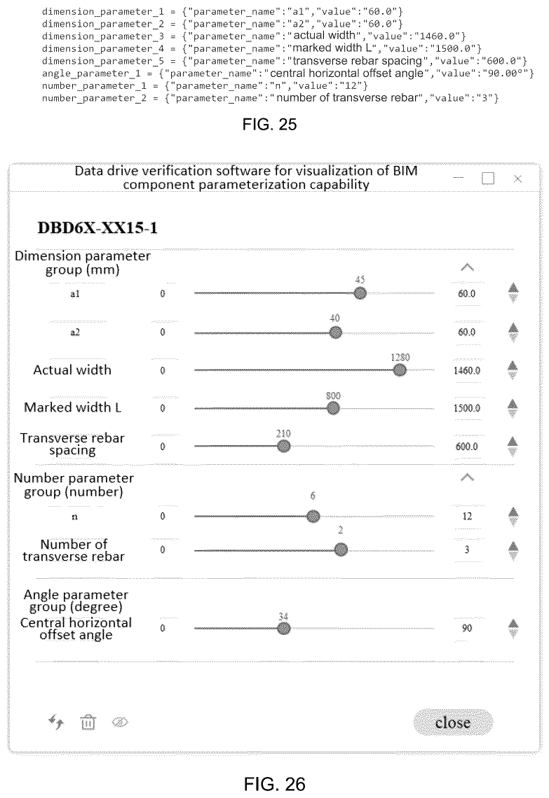

A storage dataset is formed according to the above result, parameter types and the number are dynamically generated with reference to “count” values of various classes of parameters, and component parameter names and parameter values are dynamically assigned to the variables for storage, as shown in FIG. 25.

In the present embodiment, an implementation mode of developing the drive verification software is introduced first below:

acquiring all the BIM component parameters of the BIM component, and constituting a parameter set with the BIM component parameters according to a preset format; screening out a target parameter corresponding to a set parameter type in the parameter set, and constituting a target parameter set with the target parameter corresponding to the parameter type; creating a visualization interface including the parameter type and the target parameter set; and synchronously adjusting geometry of the BIM component by adjusting the target parameter in the visualization interface, and performing drive verification on parameterization capability of the BIM component, so as to complete development of the drive verification software.

In the present embodiment, the step of creating the visualization interface including the parameter type and the target parameter set can be realized in the following manner:

correspondingly creating a BIM component parameter sub-group of the visualization interface according to the parameter type, wherein the BIM component parameter sub-group includes at least one target parameter of the parameter type corresponding thereto; creating a target parameter adjustment sliding block corresponding to the target parameter in the BIM component parameter sub-group of the visualization interface; binding the target parameter with the corresponding target parameter adjustment sliding block, to obtain the visualization interface including the BIM component parameter sub-group and the target parameter set, wherein the BIM component parameter sub-group carries information on the parameter type.

In the design of the visualization interface of the BIM component parameter, common BIM design software exists in the form of client, and visualization interface development can be effectively performed using a WPF (Windows Presentation Foundation, Windows-based user interface framework) tool. A visualization parameter adjustment sliding block is created in the visualization interface. Since the number of dimension parameters, angle parameters, and number parameters of different components are uncertain, different BIM component parameter sub-groups can be dynamically created according to final variables obtained in the above steps, and the parameter adjustment sliding block is dynamically created under the sub-groups, so that drive verification software for the visualization data of the BIM component parameterization capability has a self-adapted function.

In the present embodiment, in the drive verification software, the visualization interface may be as shown in FIG. 26.

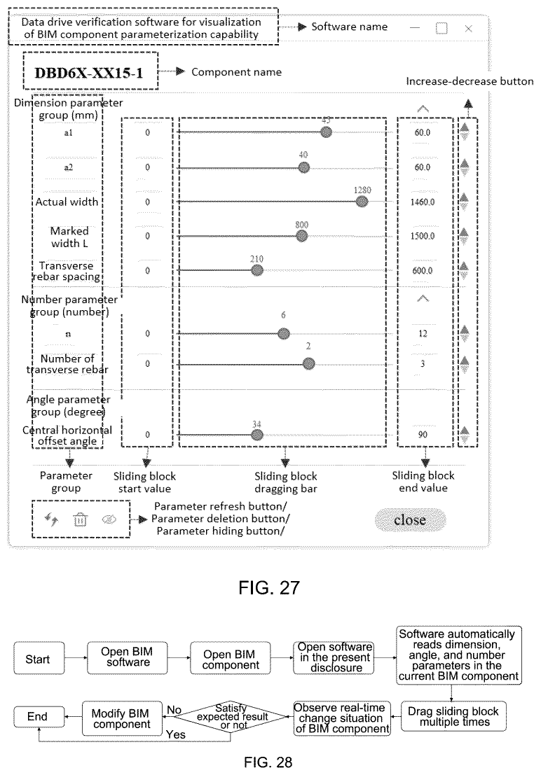

Referring to FIG. 27, the visualization interface includes software name, component name, parameter group, start value and end value of the sliding block, sliding block dragging bar, increase-decrease button, parameter refresh button, parameter deletion button, and parameter hiding button. Specifically:

software name: directly created using WPF text type label;

component name: reading name of currently opened BIM component file using the BIM software API;

parameter group: containing three types of parameter groups: the dimension parameter, the angle parameter, and the number parameter, which is directly created by text label;

start value and end value of sliding block: a default start value being 0, and the end value being a parameter value read based on the above steps;

sliding block dragging bar: a value change interval being determined by the start value and the end value of the sliding block, which is capable of displaying current value in real time;

increase-decrease button: bound with numerical values of the current sliding block dragging bar, which is capable of realizing fine tuning of parameter value;

parameter refresh button: capable of refreshing parameter situation of current BIM component;

parameter deletion button: dynamically deleting a parameter that does not need to be adjusted in the software interface, and not deleting this parameter from the BIM component; and

parameter hiding button: dynamically hiding a parameter that does not need to be adjusted in the software interface, and capable of displaying this hidden parameter after double click.

When the parameter adjusting sliding block in the visualization interface is bound with the BIM component parameter, the BIM component parameter required in the visualization interface is bound in the background. When operating in the visualization interface, required invariant data is directly read, including, e.g., BIM component name, and background program inherits INotifyPropertyChange interface, to realize the binding of WPF visualization interface panel data and background data. When the visualization interface data changes, the data is transmitted to the background by a set method, and a method/function for transmitting the data back to the BIM component is added to the set method, so that real-time transmission of the visualization interface data to the BIM component can be realized.

After the above development is completed and the developed drive verification software is installed in the BIM software, the drive verification software is opened, and the BIM component file can be opened in the visualization interface. Referring to FIG. 28, the visualization interface can automatically read the dimension parameter, the angle parameter, and the number parameter in the current BIM component, including the parameter name, the parameter value, and the number of parameters of the same class, a plurality of parameter sub-groups are adaptively created according to the number of parameters read, and a plurality of parameter adjustment sliding blocks are adaptively created according to the number of parameters in the sub-groups.

On this basis, the above visualization verification of the parameterization capability of the BIM component by adjusting the target parameter in the target visualization interface can be realized in the following manner:

adjusting the target parameter adjustment sliding block of the target parameter in the target visualization interface, and obtaining a geometry change situation of the to-be-verified BIM component after each time of adjustment; and judging whether the change situation satisfies an expected result, if not, modifying the to-be-verified BIM component, and if satisfying, ending the verification process, so as to complete the visualization verification of the parameterization capability of the to-be-verified BIM component.

In the prior art, with regard to the use of the BIM component, it generally depends on the designer's autonomous search and query, and lacks an effective method for recommended use of the BIM component.

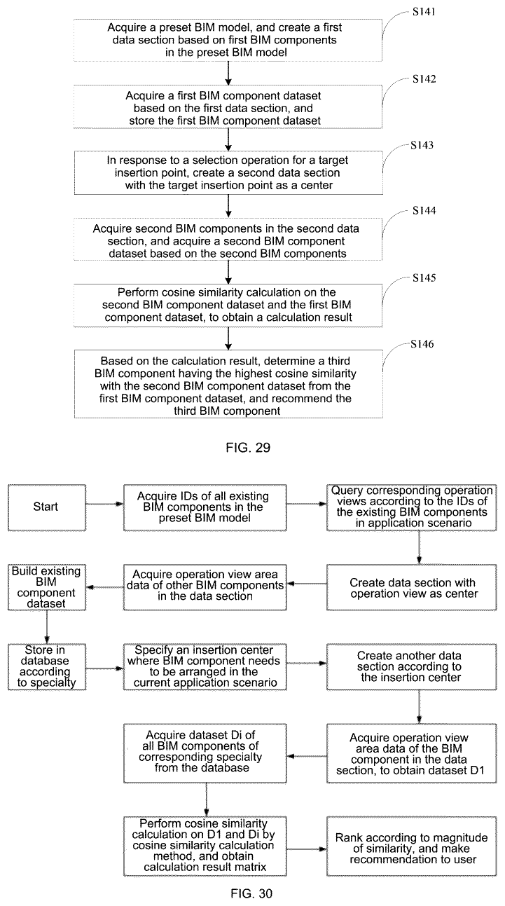

Based on this, in the creating method and application provided in the present embodiment, a mode of recommending a BIM component based on cosine similarity is provided for the above problem, referring to FIG. 29, this recommending mode can realized in the following manner:

S141, acquiring a preset BIM model, and creating a first data section based on first BIM components in the preset BIM model;

S142, acquiring a first BIM component dataset based on the first data section, and storing the first BIM component dataset;

S143, in response to a selection operation for a target insertion point, creating a second data section with the target insertion point as a center;

S144, acquiring second BIM components in the second data section, and acquiring a second BIM component dataset based on the second BIM components;

S145, performing cosine similarity calculation on the second BIM component dataset and the first BIM component dataset, to obtain a calculation result; and

S146, based on the calculation result, determining a third BIM component having the highest cosine similarity with the second BIM component dataset from the first BIM component dataset, and recommending the third BIM component.

In the present embodiment, after the user opens a preset BIM model which has been built or is being built, the system can acquire and detect the BIM model. Each preset BIM model is constituted by several BIM components, wherein the BIM components in the preset BIM model are BIM components in the digital design resource library. The system can take each BIM component in the preset BIM model as the first BIM component, and create the first data section.

Exemplarily, the system can acquire the first BIM component dataset based on the first data section. For example, the first data section of one upright column component (the first BIM component) contains an upright column, an external wall connected to the upright column, an internal wall connected to the upright column, and a door located on the wall. Then the system can build the first BIM component dataset including all the above components, and store the first BIM component dataset. The system also can associate the BIM components therein with each other in the dataset, for example, the internal wall, the external wall and so on are associated with the upright column.

In practical application, the system further may classify the first BIM components according to specialties in the first BIM component dataset, for example, further classify the first BIM components according to five participation specialties, such as building, structure, water supply and drainage, heating and ventilation, and electrics, so as recommend more accurately.

When the user wants to insert a new BIM component into the BIM model, for example, to insert another door on the wall, the user can click a specific position where the door is to be inserted, so that the system determines an insertion point, and generates the second data section with a target insertion point as a center.

If only one BIM component is included in the second data section, i.e., internal wall component, the system can determine the internal wall as the second BIM component. The system can build the second BIM component dataset based on the second BIM component, that is, build the second BIM component dataset based on the internal wall component.

Exemplarily, the system performs the cosine similarity calculation on the second BIM component dataset and the first BIM component dataset, and performs the cosine similarity calculation on the internal wall component in the second BIM component dataset and each of the upright column, the external wall connected to the upright column, the internal wall connected to the upright column, the door located on the wall, etc. in the first BIM component dataset respectively, so as to obtain a calculation result.

Exemplarily, according to the previous first BIM component dataset, it can be seen that, it should be the door that has the highest cosine similarity with the internal wall in the calculation result, then the system can determine the door as the third BIM component. In practical application, the system can determine a plurality of components having the highest similarity as the third BIM component, for example, components with top 20 cosine similarity.

After determining the third BIM component, the system can send recommendation information on the third BIM component to the user, for example, display the recommendation information to the user in the form of pop-up window, so that the user can directly select and insert, without the clicking and searching by the user.

In an embodiment of the present disclosure, after the user opens one BIM model, the system can scan this BIM model, to obtain various BIM components constituting this BIM model, then determine relevant BIM components associated with each BIM component based on each BIM component, and further form the first BIM component dataset. That is, in the present embodiment, a manner of acquiring the first BIM component dataset based on the first data section is as follows:

determining relevant BIM components corresponding to the first BIM components based on a first operation view and the first data section; and forming the first BIM component dataset based on the first BIM components and the relevant BIM components.

When the user selects one insertion point and wants to insert one BIM component at this position, the system can detect other components contained within the vicinity of this insertion point, to generate the second BIM component dataset.

In the present embodiment, the second data section can be created in the following manner:

in response to the selection operation for the target insertion point, acquiring a current operation view in the vicinity of the target insertion point; creating a second operation view based on the current operation view; and creating the second data section based on the second operation view.

On this basis, in the present embodiment, the second BIM component dataset is acquired in the following manner:

determining the second BIM components corresponding to the second operation view based on the second data section; and acquiring the second BIM component dataset based on the second BIM components.

Thus, by means of cosine similarity algorithm, a BIM component which is most relevant to the second BIM component dataset is screened out from the first BIM component dataset, and is further recommended to the user. Specifically, the cosine similarity calculation is performed on the operation view in the second BIM component dataset and the operation view in the first BIM component dataset, to obtain the calculation result.

The user can directly click to select and use, without the need of searching one by one from the library with massive BIM components, thereby reducing operation steps of the user, and improving the operation efficiency of the user. Moreover, in the process of building the BIM model and selecting the BIM component file, compared with the way of searching for a local file in the existing operation mode, by the method of recommending the component, selection efficiency of the BIM component can be greatly improved, and in combination with a specific application scenario and a cosine similarity calculation method, further utilization of the BIM component data is realized, thereby solving the technical problem of relatively low use efficiency of the BIM component.

Exemplarily, as shown in FIG. 30, the dataset of existing BIM components (the first BIM components) is first built. First, the user opens the preset BIM model, and after traversing the preset BIM model, the system acquires IDs of all existing BIM components in the preset BIM model, for example, all of the upright column, the external wall, the internal wall, and the door have their own corresponding number ID. Then, in various operation views (plane, elevation, and section), various operation views corresponding to the BIM components are queried according to the IDs of the existing BIM components (for example, corresponding plane operation view, elevation operation view, and sectional operation view are queried according to the ID of the upright column), to create the data section with the operation view of the BIM component as a center. Subsequently, operation view area data of other BIM components in the data section is acquired, so far, an existing BIM component application scenario dataset (the first BIM component dataset) is completed, and the dataset is saved in the database according to specialty to be ready for use in next step.

Application scenarios in the operation of building engineering BIM component can be classified according to participation specialties and operation view dimensions. In the above, the participation specialties can be classified into five specialties, i.e., building, structure, water supply and drainage, heating and ventilation, and electrics, and the operation views can be three classes of views, i.e., plane view, elevation view, and sectional view. Specific application scenarios should be calculated in a combined manner, and there may be 15 categories of the BIM component application scenarios and views in total.

Based on the above 15 categories of the BIM component application scenarios and views, the data section is created with the BIM component as a center. The system first traverses the BIM components in the views, traverses existing BIM components in various views in various specialties. In the current view, a single BIM component is taken as a center for data extraction. In the above, the BIM component only refers to standardized BIM component that can be transferred in a file form. A method of traversing existing BIM components in various views in various specialties can be realized by a BIM software API interface.

When the view is a plane view, an elevation view, and a sectional view, operation views of all BIM components in the current view and relevant data thereof are acquired, to form a BIM component set, including BIM component instance ID, BIM component name, position of center of gravity G(x, y), and horizontal and vertical coordinate values x₁, y₁), (x₂, y₂), (x₃, y₃), (x₄, y₄) . . . (xₙ, yₙ) of BIM-component plane projection geometric profiles, wherein n is the number of sides of projections of the BIM component on the plane, the elevation and the section, and projected two-dimensional figures are irregular polygon X.

In the above, formulas for solving coordinates of the position of center of gravity G(x, y) of the irregular polygon X are as shown in Formula 1 and Formula 2.

$$x = \frac{{\sum }_{m}^{n = 1} {G}_{n x} {S}_{n}}{{\sum }_{n = 1}^{m} {S}_{n}} \qquad ( Formula 1 )$$

$$y = \frac{{\sum }_{m}^{n = 1} {G}_{n y} {S}_{n}}{{\sum }_{n = 1}^{m} {S}_{n}} \qquad ( Formula 2 )$$

In the above, the irregular polygon X can be sectioned into m limited simple figures X₁, X₂, X₃, . . . , Xₙ, . . . , Xₘ, wherein n represents an nth simple figure, a center of gravity of these simple figures is Gₙ, and an area thereof is Sₙ.

Taking the BIM component instance ID data as query basis, all component instances in the BIM component set are traversed in the current view, and centering on the position of center of gravity G(x, y) of a single instance component, a data matrix section with l as side length is formed, where a value of l is max(5000 nm 2 max(|yₖ₊₁−yₖ|, |xₖ₊₁−xₖ|)nm), where k is a kth vertex of a plane projection of a certain BIM component, with a value range of 1≤k≤n−1.

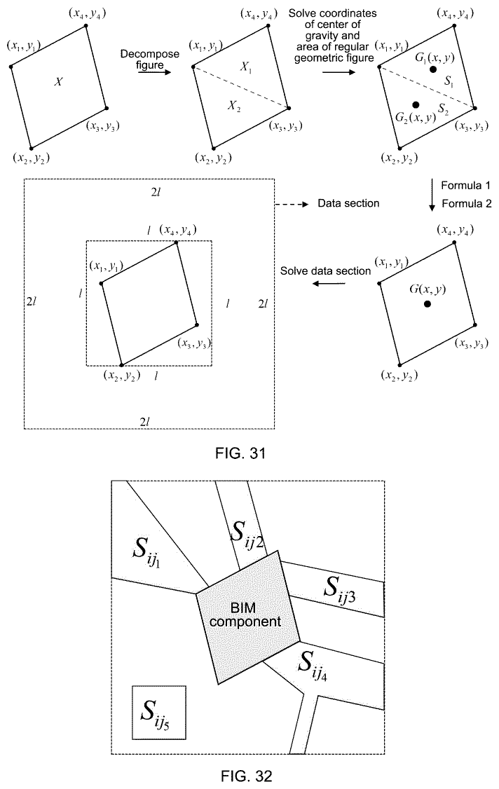

Taking the projection being a quadrangular BIM component as an example, a process of creating the data section is as shown in FIG. 31.

Based on the data section, relevant other component data in the data section is acquired. In the above, other components can be distinguished according to the specialties, as shown in Table 3.

TABLE 3
Specialties and Corresponding Components

| Specialty | Component |
|---|---|
| Building | Building external wall, building internal wall, building column, door, |
| specialty | window, roof, floor, curtain wall, ceiling, stair, elevator, escalator, |
| | footpath, ramp, step, apron slope, open ditch, railing, awning, balcony, |
| | terrace, coping, deformation joint, equipment installation opening, |
| | parking lot, other components |
| Structure | Bed course, isolated foundation, strip foundation, raft foundation, pile |
| specialty | foundation, bearing platform, waterproof board, drain pit, drainage |
| | ditch, retaining wall, shear wall, structural column, steel reinforced |
| | column, column cap, ladder post, beam, steel reinforced beam, |
| | haunched beam, hoisting beam, ramp beam, beam-faced concrete dwarf |
| | wall, beam-bottom concrete hanging plate, floor plate, roof panel, step |
| | plate, platform plate, ramp plate, bay window plate, balcony slab, air- |
| | conditioning plate, canopy board, bridging piece, steel beam, steel |
| | column, profiled metal sheet, steel-structural rod, steel ladder beam, |
| | tread, platform plate, bolt, gusset plate, stiffening plate, lacing bar, |
| | stiffening rib, hanger, constructional column, lintel, built-in fitting |
| Water | Water tank, pressurized equipment, water heater, heat exchanger, solar |
| supply and | heat collection equipment, hot water unit, heat pump set, lifting device, |
| drainage | grease interceptor, water softening equipment, filtration equipment, |
| specialty | membrane treatment equipment, harmful substance removing |
| | equipment for basement, disinfection equipment, cooling tower, fire |
| | pump, high-place fire protection water tank, pressure boosting and |
| | stabilizing type water supply equipment for fire-protection, fire pump |
| | adapter, fire hydrant, spray head, alarm valve set, water flow indicator, |
| | water-test equipment, large-space intelligent active control sprinkler |
| | device, stationary fire water monitor, watermist fire extinguishing |
| | equipment, gas fire extinguishing equipment, foam fire extinguishing |
| | equipment, fire-fighting equipment, vertical pipe, horizontal pipeline |
| | (>DN50), horizontal pipeline (≤DN50), valve, meter, filter, rotational- |
| | flow preventer, water suction bellmouth, corrugated compensator, |
| | flexible rubber joint, metal hose, cleanout, access hole, ventilation cap, |
| | roof drain, bushing |
| Heating and | Air handling unit, fan coil, variable air volume terminal device, multi- |
| ventilation | connected air conditioning outdoor unit, multi-connected air |
| specialty | conditioning indoor unit, radiator, fan heater, fan, air curtain, water |
| | chilling unit, lithium bromide absorption unit, heat exchange |
| | equipment, heat pump unit, boiler, air duct, air duct valve, silencer, air |
| | vent, water pipeline, Freon pipe, water pipe valve, circulating water |
| | pump, expansion water tank, water softening treatment device, |
| | distribution manifold |
| Electric | High-voltage distribution cabinet, substation intelligent host, direct |
| specialty | current screen, signal screen, low-voltage distribution cabinet, |
| | distribution box (including control box), transformer, house generator, |
| | uninterruptible power supply equipment box (UPS), emergency power |
| | supply equipment box (EPS), fire-emergency lighting and evacuate |
| | indicating luminaire, general lighting fixture, switch, power supply |
| | socket, equipotential terminal box, lightning-protection lightning |
| | arrester, lightning protection down-conductor, grounding grid, bus duct, |
| | cable tray, ladder assembly, tray, host of fire automatic alarm control |
| | system equipment, fire automatic alarm system terminal device, fire- |
| | emergency lighting and evacuation indication system centralized |
| | controller, host of fire power supply monitoring system equipment, host |
| | of electrical-fire automatic alarm system equipment, host of fire door |
| | monitoring system equipment, fire door monitoring system terminal |
| | device, host of security and protection integrated management system |
| | equipment, host of intrusion alarm system equipment, intrusion alarm |
| | system terminal device, host of video protection and surveillance |
| | system equipment, display screen, video protection and surveillance |
| | system terminal device, host of access control system equipment, access |
| | control system terminal device, electronic inspection management |
| | system equipment, host of visitor intercom system equipment, indoor |
| | extension of visitor intercom system, parking garage (lot) management |
| | system equipment, cabinet of communication access system equipment, |
| | communication access system terminal device, wiring cabinet of |
| | telephone switching system, telephone switching system terminal |
| | device, cabinet of information network system equipment, information |
| | network system terminal device, cabinet of integrated wiring system |
| | equipment, integrated wiring system terminal device, indoor mobile |
| | communication coverage system equipment, satellite communication |
| | system equipment, cable TV and satellite TV receiving system |
| | equipment, host of broadcasting system equipment, broadcasting |
| | system terminal device, conference system equipment, information |
| | guidance and distribution system equipment, clock system equipment, |
| | construction-equipment monitoring system equipment, building energy |
| | efficiency monitoring system equipment, cable trough box, ladder |
| | assembly, tray |

Then the BIM components are numbered according to the specialties, the numbers are corresponding to the sequence of other BIM components in the above table, and the BIM components in various specialties are expressed as follows:

building specialty: {A₁, A₂, . . . , Aⱼ, . . . , Aₐ}, where A represents the building specialty, a represents the number of all BIM components in the building specialty, and j represents a jth building specialty component;

structure specialty: {T₁, T₂, . . . , Tⱼ, . . . , Tₜ}, where T represents the structure specialty, t represents the number of all BIM components in the structure specialty, and j represents a jth structure specialty component;

water supply and drainage specialty: {P₁, P₂, . . . , Pⱼ, . . . , P}, where P represents the water supply and drainage specialty, p represents the number of all BIM components in the water supply and drainage specialty, and j represents a jth water supply and drainage specialty component;

heating and ventilation specialty: {M₁, M₂, . . . , Mⱼ, . . . , Mₘ}, where M represents the heating and ventilation specialty, m represents the number of all BIM components in the heating and ventilation specialty, and j represents a jth heating and ventilation specialty component; and

electric specialty: {E₁, E₂, . . . , Eⱼ, . . . , Eₑ}, where E represents the electric specialty, e represents the number of all BIM components in the electric specialty, and j represents a jth electric specialty component.

In the above, other relevant BIM component data in the data section is acquired, and taking the application scenario and view of the BIM component as objects, other BIM component types in the data section, and projection areas Sᵢⱼ of other BIM components on the projection plane are acquired, where i represents an ith specialty, with a value range of {A, T, P, M, E}, and j represents a j th component in a certain specialty.

As shown in FIG. 32, Sᵢⱼ_{ᵢ}˜Sᵢⱼ_{ᵢ}, represent areas of 5 other BIM components in a certain specialty, and areas of remaining BIM components not in the data section are 0, where Sᵢⱼ represents a horizontal projection area of a jth BIM component in the ith specialty, and Arabic numerals 1˜5 only represent certain 5 other BIM components in this BIM component.

After that, in the process of designing and building the BIM model in the BIM software by the user, and designating an insertion center where a BIM component needs to be arranged in the current application scenario, through the designated insertion center, the system can create another data section with coordinates of position of the insertion center as center and a side length of 5000 mm, and acquire area data of operation views of the BIM component in this data section, to obtain a dataset D1 of the current application scenario.

For example, if the user clicks the internal wall, the system builds a data section with the clicked position of the internal wall as center and a side length of 5000 mm. Assuming that there is only area data of plane projection of the internal wall in the data section, the system can build the dataset D1 of the current application scenario based on the area data of the plane projection of the internal wall. It should be noted that the data section may include a plurality of area data of the plane projection, corresponding to different components. After that, the system can determine that the corresponding specialty is the building specialty according to the internal wall, acquire the dataset Di of all BIM components of the corresponding specialty from the database, perform cosine similarity calculation on D1 and Di by the cosine similarity calculation method, and obtain a calculation result matrix. The BIM components are ranked according to magnitude of similarity, to make recommendation to the user. For example, the BIM components are retrieved from the BIM component library according to the calculation result and ranked according to the calculation result, for example, obtaining recommendation ranking of top 20 BIM components, and recommending the same to the user.

In the embodiments of the present disclosure, the cosine similarity is taken as a scenario-based BIM component similarity recommending method, and an expression manner thereof is as follows:

$$cos ( θ ) = \frac{{\sum }_{i = 1}^{n} ( {X}_{i} \times {Y}_{i} )}{\sqrt{{\sum }_{i = 1}^{n} {( {X}_{i} )}^{2}} \times \sqrt{{\sum }_{i = 1}^{n} {( {Y}_{i} )}^{2}}} = \frac{a \cdot b}{‖ a ‖ \times ‖ b ‖}$$

where a and b are two n-dimensional vectors.

In the above, when a cosine value cos(θ) gets closer to 1, it indicates that an included angle between the vectors a and b gets closer to 0 degrees, that is, the two vectors are more similar, and when the included angle is equal to 0, the two vectors are equal.

It can be obtained from the previous building process of the dataset that the data vectors constituted by the horizontal projection areas of each BIM component in each specialty and other BIM components in the data section are all finite-dimensional vectors, and vector expression modes of various BIM components in various specialties are as follows:

building specialty: Aⱼ=(Sⱼ_{₁}, Sⱼ_{₂}, Sⱼ_{₃}, . . . , Sⱼ_{ₐ}), where A is the building specialty, j represents the jth component in the building specialty, and a represents the number of all BIM components in the building specialty;

structure specialty: Tⱼ=(Sⱼ_{₁}, Sⱼ_{₂}, Sⱼ_{₃}, . . . , Sⱼ_{ₛ}), where T is the structure specialty, j represents the jth component in the structure specialty, and s represents the number of all BIM components in the structure specialty;

water supply and drainage specialty: Pⱼ=(Sⱼ_{₁}, Sⱼ_{₂}, Sⱼ_{₃}, . . . , Sⱼ_{ₚ}), where P is the water supply and drainage specialty, j represents the jth component in the water supply and drainage specialty, and p represents the number of all BIM components in the water supply and drainage specialty;

heating and ventilation specialty: Mⱼ=(Sⱼ_{₁}, Sⱼ_{₂}, Sⱼ_{₃}, . . . , Sⱼ_{ₘ}), where M is the heating and ventilation specialty, j represents the jth component in the heating and ventilation specialty, and m represents the number of all BIM components in the heating and ventilation specialty; and

electric specialty: Eⱼ=(Sⱼ_{₁}, Sⱼ_{₂}, Sⱼ_{₃}, . . . , Sⱼ_{ₑ}), where E is the electric specialty, j represents the jth component in the electric specialty, and e represents the number of all BIM components in the electric specialty.

It should be noted that, the above letter “j” is only used for description in the embodiments of the present disclosure, and different specialties can be represented by different letters, which has no conflict in practical applications.

In the current BIM model view, coordinates of the position of center of gravity where a BIM component is to be inserted is specified, a data section is formed, and an expression manner for acquiring the data vector in the data section is as follows:

D=(S₁, S₂, S₃, . . . , Sₖ)

where Sₖ is the BIM component area in the data section in the current BIM model view, k has different value ranges according to different specialties: building specialty: 0≤k≤a, structure specialty: 0≤k≤s, water supply and drainage specialty: 0≤k≤p, heating and ventilation specialty: 0≤k≤m and electric specialty: 0≤k≤e.

The cosine similarity between the two is:

$$cos ( θ ) = \frac{D \cdot B}{‖ D ‖ \times ‖ B ‖}$$

where according to different BIM component application scenarios, a value set of B is any one of {Aⱼ, Tⱼ, Pⱼ, Mⱼ, Eⱼ}.

The cosine similarity matrixes calculated for various specialties are as follows:

building specialty: cos(θ)_{A}=[cos(θ)₁, cos(θ)₂, . . . , cos(θ)ₐ]^{T}

structure specialty: cos(θ)_{T}=[cos(θ)₁, cos(θ)₂, . . . , cos(θ)ₜ]^{T}

water supply and drainage specialty: cos(θ)_{P}=[cos(θ)₁, cos(θ)₂, . . . , cos(θ)ₚ]^{T}

heating and ventilation specialty: cos(θ)_{M}=[cos(θ)₁, cos(θ)₂, . . . , cos(θ)ₘ]^{T}

electric specialty: cos(θ)_{E}=[cos(θ)₁, cos(θ)₂, . . . , cos(θ)ₑ]^{T}.

For BIM component recommendation under different application scenarios in different specialties, the BIM components can be ranked in a descending order of cosine similarity matrix median values calculated for various specialties, and a BIM component with the biggest cosine similarity value is recommended preferentially.

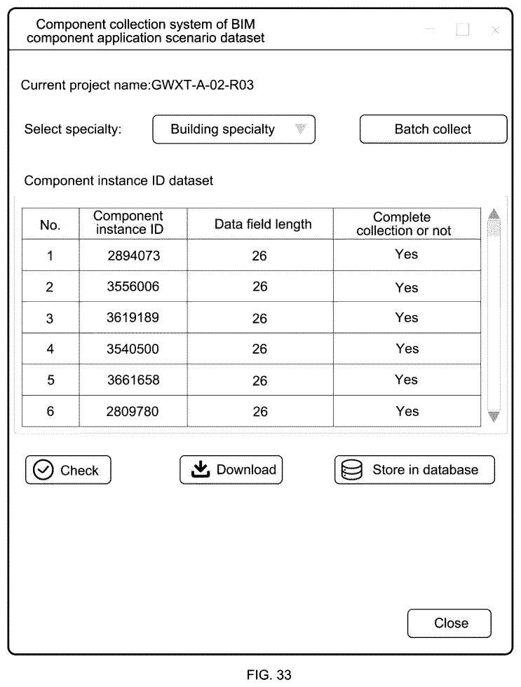

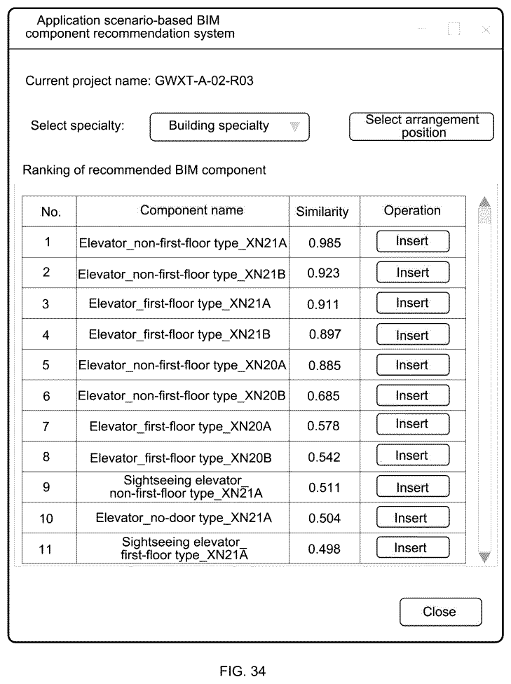

In practical applications, the present method can be combined with the BIM software in the form of external software or internal plug-in. For example, installation and use are performed in the BIM software in the form of software. Firstly, “component collection system for BIM component application scenario dataset” software (a running interface is as shown in FIG. 33) needs to be installed, and runs in a plurality of BIM model projects, to form a dataset of existing BIM components, and store the same in a database. Secondly, “application scenario-based BIM component recommendation system” software (a running interface is as shown in FIG. 34) is installed, and after the software runs, the user selects a position where the BIM component needs to be arranged, the system can automatically give the ranking of the BIM components in the current application scenario, the user selects an appropriate BIM component and uses an “Insert” function to load the selected BIM component into the current BIM model and use the same, and the software is closed after being used.

The flows of how to create the BIM component in a plurality of different creating modes, how to realize batch addition of parameters to the BIM component, how to perform parameter visualization verification on the BIM component, and how to recommend the BIM component based on the cosine similarity mode are introduced in the above.

In addition, in the process of building the BIM model, the model is usually built with the BIM component instance as a basic unit, but at present, the application capability of BIM component instances of numerous building enterprises develop slowly, when the designer builds the BIM model, the designer usually needs to continuously select and adjust the BIM component instances manually in a BIM component instance resource library so as to form the BIM model conforming to design purpose of the model. Such a scheme of building a BIM model has the problems of long time consumption, large human power consumption, and large multiplexing difficulty, and cannot help the designer build the BIM model quickly.

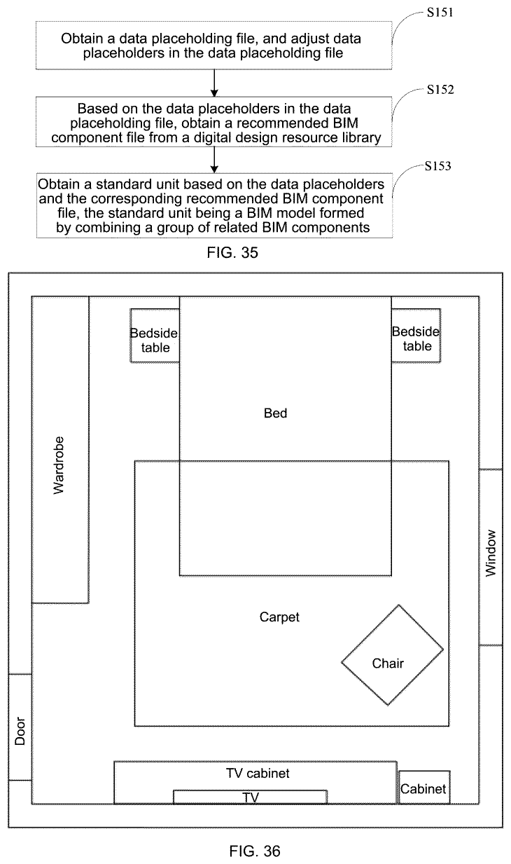

Therefore, based on the above consideration, in the present embodiment, a mode of building a BIM model based on data placeholding in the above step S15 is used to solve the problems. Specifically, referring to FIG. 35, in the present embodiment, the mode of building a BIM model based on data placeholding may be realized in the following manner:

S151, obtaining a data placeholding file, and adjusting data placeholders in the data placeholding file;

S152, based on the data placeholders in the data placeholding file, obtaining a recommended BIM component file from a digital design resource library; and

S153, obtaining a standard unit based on the data placeholders and the corresponding recommended BIM component file, wherein the standard unit is a BIM model formed by combining a group of related BIM components.

In the present embodiment, a manner of obtaining the data placeholding file may be a manner of rendering a data placeholding view, or a manner of loading a historical data placeholding file, and the two manners may be used alternatively or simultaneously.

In the present embodiment, the data placeholder is a single data block of limited data, and each data placeholder stores a plurality of pieces of data information, including: name data, position data, dimension data, and type data. According to the data in the data placeholder, the BIM component file can be automatically acquired from the BIM component library and a BIM component instance can be generated in situ. In the above, the position data represents layout of each data placeholder, the dimension data represents dimension of a BIM component instance represented by the data placeholder, and the type data represents BIM component file type. As shown in FIG. 36, each rectangle is a concretized representation of the data placeholder.

Data placeholding view: the data placeholding view is a visualization interface constituted by data placeholders. As shown in FIG. 36, a plurality of concretized data placeholders are combined into one data placeholding view.

Data placeholding file: the data placeholding file is a file storing all data placeholders in the JSON format.

In the present embodiment, when the data placeholding file is obtained in the manner of rendering the data placeholding view, it can be realized in the following manner:

creating a new blank data placeholding file; rendering data placeholders; determining a current application scenario, and loading the data placeholders and the current application scenario into the blank data placeholding file, to obtain the data placeholding file.

The data placeholding view is constituted by data placeholders, and the data of each data placeholder includes name data, position data, dimension data, and type data, and a generating mode thereof depends on a Revit plug-in custom-developed in the present disclosure.

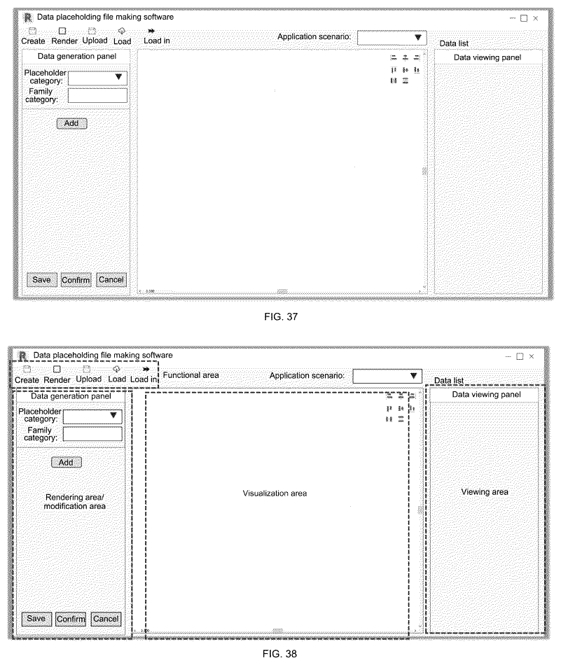

The data placeholding file generates a plug-in front-end framework by using WPF, and an initial interface of the plug-in in the present embodiment is as shown in FIG. 37. In the disclosure, a plug-in page is divided into five areas by xaml document: a functional area, a rendering area, a visualization area, a data viewing area, and a data modification area, as shown in FIG. 38. The functional area is used for functions of creating and saving a data placeholding file and loading the historical data placeholding file; the rendering area is used for acquiring information necessary for creating the data placeholding view; the visualization area is used for concretizing all data placeholders; the data viewing area is used for viewing detailed information of all data placeholders; and the data modification area is used for modifying information of a single data placeholder.

In order to realize the basic function of the data placeholder: according to the data in the data placeholder, the BIM component file is automatically acquired from the resource library and a BIM component instance is generated in situ. When rendering the data placeholder, two basic functions need to be realized: refining data placeholder and precisely rendering data placeholder.

In the present embodiment, the data placeholder can be rendered in the following manner:

defining a plurality of data placeholder categories according to different BIM component types; determining information required under each data placeholder category; building a standard coordinate system, and for each data placeholder category, rendering a corresponding data placeholder in the standard coordinate system based on acquired information corresponding to the data placeholder category.

In the present embodiment, in the processing of data placeholder refining, the data placeholder needs to be refined into many forms according to the category of the BIM component represented by the data placeholder. There are various ways of placing one BIM component in the Revit, resulting in various ways of automatically placing the BIM component using the Revit API. The system BIM component and the standard BIM component are placed in different ways. For example, a system BIM component wall is placed through a wall-specific “Wall” class, and the standard BIM component is placed using the following function:

Document.Create.NewFamilyInstance( );

information required for placing different BIM components in the system BIM components in the Revit is different: a door can be placed only with a host (wall) and coordinates, while a window can be placed accurately by further requiring a piece of height information. Therefore, to place the BIM component instance according to the data placeholder data, the data of the data placeholder needs to be refined.

In the present embodiment, first, the data placeholders are refined into 4 classes according to the categories of the BIM components: a first-class placeholder, a second-class placeholder, a third-class placeholder, and a fourth-class placeholder.

Before defining the categories of the data placeholders, a definition of host element needs to be specified. The host element refers to an element that can be attached by some elements, for example, ceiling, as a host element, can be attached by a ceiling lamp, and wall, as a host element, can be attached by a door. The four classes of data placeholders are defined as follows.

The first-class placeholder: the first-class placeholder represents data placeholder of a class of BIM component, wherein such BIM component specifically refers to wall.

The second-class placeholder: the second-class placeholder represents data placeholder of a class of BIM component, wherein instances of such class of BIM component require a host element and does not require height information when being placed. For example, the data placeholder of door is the second-class placeholder, and when placing the door, the Revit needs to provide a wall but does not need to provide height information of the door.

The third-class placeholder: the third-class placeholder represents data placeholder of a class of BIM component, wherein instances of such class of BIM component require a host element and height information as well when being placed. For example, the data placeholder of window is the third-class placeholder, and when placing the window, the Revit needs to provide a wall and height information.

The fourth-class placeholder: the fourth-class placeholder represents data placeholder of a class of BIM component, wherein instances of such class of BIM component only require coordinate information when being placed. For example, a data placeholder of table is the fourth-class placeholder, and the Revit can create a BIM component instance of the table only with one piece of coordinate information.

The data placeholders are divided into four classes according to the categories of the BIM components, and since information required for placing instances of BIM components of different categories is different, information contained in different data placeholders is al so different.

The first-class placeholder: when placing a wall, the Revit requires a start point of the wall, an end point of the wall, and a wall width.

The second-class placeholder: when placing an instance of this category of BIM component, the Revit requires a BIM component file, a host element, and a planar position of the BIM component instance relative to the host element. For example, when placing a door, the Revit needs a BIM component file of the door, a wall, and position information of the door on the wall.

The third-class placeholder: when placing an instance of this category of BIM component, the Revit requires a BIM component file, a host element, and a planar position of the BIM component instance relative to the host element, and height information about placing the BIM component instance. For example, when placing a window, the Revit needs a BIM component file of the window, a wall, a planar position of the window on the wall, and a placement height of the window.

The fourth-class placeholder: when placing an instance of this category of BIM component, the Revit requires a BIM component file, and coordinates. For example, when placing a table, the Revit requires a BIM component file of the table and coordinates of the table.

Therefore, information on the four classes of data placeholder data can be defined, as shown in Table 4.

TABLE 4
Categories of Data Placeholders and Data Placeholder Information

| Category of data | |
|---|---|
| placeholder | Data placeholder information |
| First-class | Start point of wall, end point of wall, and wall width |
| placeholder | |
| Second-class | BIM component type, host element, coordinates (which need to be |
| placeholder | on the data placeholder of the host element), object width, object |
| | length, rotational angle |
| Third-class | BIM component type, host element, coordinates (which need to be |
| placeholder | on the data placeholder of the host element), height, object width, |
| | object length, rotational angle |
| Fourth-class | BIM component type, coordinates, object width, object length, |
| placeholder | rotational angle |

In the above, the data of the object width, the object height, and the rotational angle are not used for placing the BIM component instance, but for the purpose of visualizing the data placeholder.

In the precise rendering of data placeholder, the rendering of data placeholder needs to be accurately positioned, to ensure that the BIM component instance is placed in an accurate position.

First step: determining coordinate axes

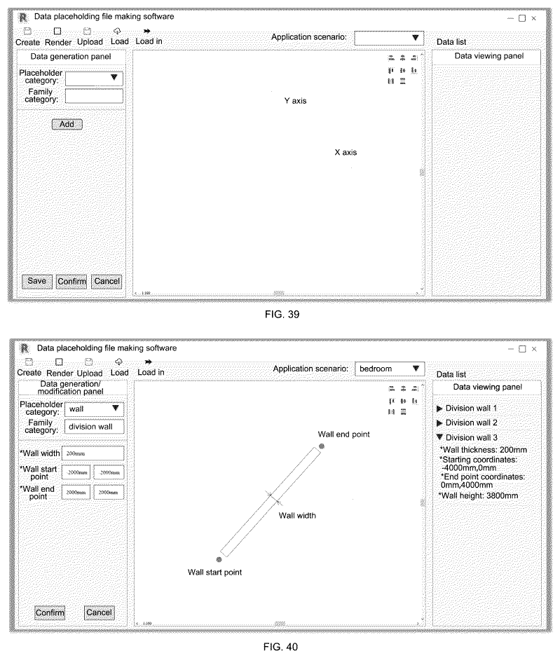

For precise rendering of data placeholder, the coordinate axes need to be determined first. In the present embodiment, a standard Cartesian coordinate system is used, as shown in FIG. 39. X coordinate system is horizontally to the right on the page, Y axis is horizontally upward on the page, and Z axis is outwards perpendicular to the screen. An origin of the coordinate axis is located at center of the rendering area. X-Y plane has the same current level as that of the Revit.

Second step: rendering the first-class placeholder

Information on the BIM component type, the start point of wall, the end point of wall, and the wall width required by the first-class placeholder is acquired through an input box in the rendering area.

Second step: rendering the second-class placeholder

Information on the BIM component type, coordinates, object width, object height, and rotational angle required by the second-class placeholder is acquired through the input box in the rendering area. The host element required by the second-class placeholder is acquired by clicking an existing placeholder in the visualization area.

Third step: rendering the third-class placeholder

Information on the BIM component type, coordinates, object width, object height, rotational angle, and host element required by the third-class placeholder is acquired by the same method as in step 2. The height information required by the third-class placeholder is acquired through the input box in the rendering area.

Fourth step: rendering the fourth-class placeholder

Information on the BIM component type, coordinates, object width, object height, and rotational angle required by the fourth-class placeholder is acquired through the input box in the rendering area.

Fifth step: viewing a rendering result for the data placeholder in the visualization area

The visualization area is configured to display the rendered data placeholders. Each rendered data placeholder in the visualization area is shown by a rectangle, which rectangle can be determined by four corner points.

The first-class placeholder: a line is determined in the Cartesian coordinate system of the visualization area through the start point of the wall and the end point of the wall, and this line is shifted toward the vertical direction by half of the wall width, so that visualization of the first-class placeholder can be obtained, as shown in FIG. 40.

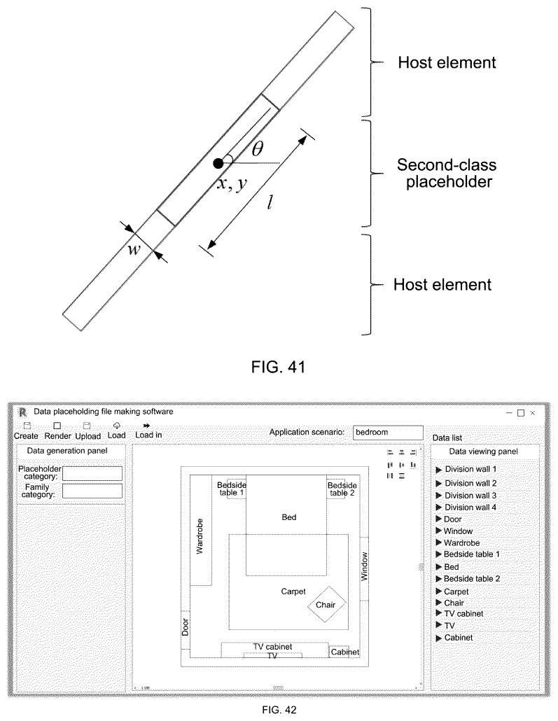

The second-class placeholder: after the second-class placeholder is visualized, information that can be represented by a single rectangle is as shown in FIG. 41. In FIG. 41, x and y represent coordinate information in the data placeholder, θ represents rotational angle information in the data placeholder, w represents object height information in the data placeholder, and l represents object width information in the data placeholder. A point can be determined in the Cartesian coordinate system of the visualization area through the coordinates (x, y). A rectangle can be determined through the object width w, the object length l, and the coordinates (x, y), and then by rotating the rectangle counterclockwise around a positioning center by θ degrees, the four corner points of the matrix can be obtained as follows:

$$( x + \frac{w}{2} sin θ - \frac{l}{2} cos θ , y - \frac{w}{2} cos θ - \frac{l}{2} sin θ ) , ( x - \frac{w}{2} sin θ - \frac{l}{2} cos θ , y + \frac{w}{2} cos θ - \frac{l}{2} sin θ )$$

$$( x + \frac{w}{2} sin θ + \frac{l}{2} cos θ , y - \frac{w}{2} cos θ + \frac{l}{2} sin θ ) , ( x - \frac{w}{2} sin θ + \frac{l}{2} cos θ , y + \frac{w}{2} cos θ + \frac{l}{2} sin θ ) .$$

The third-class placeholder: the third-class placeholder can be visualized in the same way as the second-class placeholder.

The fourth-class placeholder: the third-class placeholder can be visualized in the same way as the second-class placeholder.

To render the data placeholding view, a unified scenario represented by all data placeholders in the current file needs to be determined. The application scenario may be: a living room, a kitchen, a toilet, a hotel lobby, an industrial plant, and the like. After the current application scenario is determined, the application scenario is stored in the data placeholding file along with all the placeholder data. In a placeholder storage database, the data placeholders are classified according to application scenarios, so that the efficiency of retrieving the data placeholding file can be improved. For example, when the designer needs to design a living room in the Revit, the designer can select a data placeholding file in which the application scenario is a living room from the placeholder storage database, and select one therefrom and load the same into the Revit, so that a standard unit of living room can be generated. An example of rendering result of the data placeholding view is as shown in FIG. 42.

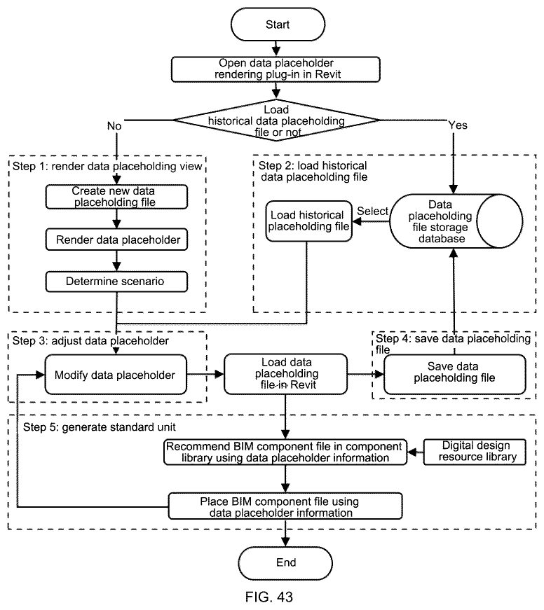

It can be seen from the above that the data placeholding file further can be obtained by loading the historical data placeholding file. In other words, an overall process of building the BIM model based on the data placeholding may be as shown in FIG. 43, wherein step 1 and step 2 can be executed simultaneously or alternatively.

The manner of loading the historical data placeholding file can rapidly generate a data placeholding file and import the same into the Revit to generate a standard unit. Loading the historical data placeholding file can reduce the time for making the data placeholding view so as to reduce the time for making the standard unit.

The historical data placeholding file is stored in the placeholder storage database, and the required data placeholding file can be quickly retrieved according to the application scenario. The historical data placeholding file is loaded into the plug-in, and this file can be directly used, and loaded into the Revit to generate the standard unit, or this file can be adjusted and then loaded into the Revit to generate the standard unit. Compared with creating a new data file placeholding file from scratch, loading the historical data placeholding file to directly use or fine-adjust the file can save a lot of time for the user.

Loading the history data placeholding file is realized by the following method:

first step: linking a “Load” button on the page to a data placeholding file storage database through C# program;

second step: saving all data placeholding files in the database in a JSON format; and

third step: parsing the JSON files and loading the parsed JSON files into a placeholder rendering plug-in.

In the above, with regard to the first step, it is in detail as follows:

calling the OpenFileDialog class, and instantiating this class to pop up a file dialog box. In the present embodiment, attributes of this class are set, including title: the title of the file dialog box; and Filter: filtering a file type to be selected. In the present embodiment, the Filter can be used to filter out all files not in the JSON format.

In the above, the JSON format in the second step is detailed as follows:

JSON, a lightweight data interchange format, is easy to read and write by users. Objects and array types are often represented using JSON. In the present embodiment, the placeholder information and the scenario information are an object and array type, and therefore can be stored in the JSON format.

An outermost layer of the JSON file is an object, and the object first stores an application scenario through “scene” key, and then takes an array that stores all placeholder information in the file as a value in “placeholder” key. The four types of placeholder information are represented by four objects, respectively.

First object: the first-class placeholder

In the above, “name” attribute represents name of the first-class placeholder; “id” attribute represents ID of the first-class placeholder, and is represented by splicing random numbers and current time; “start” attribute represents a start point of the first-class placeholder; “end” attribute represents an end point of the first-class placeholder; and “width” attribute represents wall width of the first-class placeholder.

Second object: the second-class placeholder

In the above, “name” attribute represents name of the second-class placeholder; “id” attribute represents ID of the second-class placeholder, and is represented by splicing random numbers and current time; “host” represents ID of a placeholder corresponding to a required host element when placing the second-class placeholder; “coordinate” attribute represents position coordinates for placing the second-class placeholder; “width” represents object width of the second-class placeholder; “height” represents object height of the second-class placeholder; and “angle” represents rotational angle of the second-class placeholder.

Third object: the third-class placeholder

In the above, “name” represents name of the third-class placeholder; “id” represents ID of the third-class placeholder; “host” represents ID of a placeholder corresponding to a required host element when the third-class placeholder is placed; “coordinate” represents position coordinates for placing the third-class placeholder; “heightByLevel” represents height of the third-class placeholder relative to the current level; “width” represents object width of the third-class placeholder; “height” represents object height of the third-class placeholder; and “angle” represents rotational angle of the third-class placeholder.

Fourth object: the fourth-class placeholder

In the above, “name” represents name of the fourth-class placeholder; “id” represents ID of the fourth-class placeholder, “coordinate” represents position coordinates for placing the fourth-class placeholder; “width” represents object width of the fourth-class placeholder; “height” represents object height of the fourth-class placeholder; and “angle” represents rotational angle of the fourth-class placeholder.

In the above, parsing the JSON file in the third step is detailed as follows:

since the JSON file stores a single piece of data placeholder information in the form of object, and stores information on all data placeholders in the form of array, in the process of parsing the file, C# calls JArray.Parse( ) command and stores all data placeholder information in the JArray format, and individual information of each data placeholder can be acquired by traversing placeholder data in the JArray format through foreach.

After the data placeholding file is parsed, each piece of data placeholder information is placed in the rendering area, the visualization area, and the viewing area of the front-end plug-in.

After creating the new data placeholding file and/or after loading the historical data placeholding file, the program needs to have the function of making the user adjust the data placeholder. In particular, when the user needs to quickly make a standard unit conforming to the requirement in the Revit, the user can make the standard unit by loading the historical data placeholding file and quickly adjusting the same partially. Therefore, by adjusting the data placeholder in a convenient and rapid manner, the efficiency of making the standard unit can be greatly accelerated, and the utilization capability of the BIM component file and the data placeholder can be improved.

In the present embodiment, the data placeholder can be adjusted through cooperation of the rendering area, the visualization area, and the viewing area.

1) The rendering area cooperates with the visualization area and the viewing area.

The data placeholder data is input into the rendering area, and correctness of the data placeholder data can be checked in the visualization area.

After being input into the rendering area, the placeholder data is displayed in the viewing area using a front-end WPF code, and detailed information of all data placeholders can be checked in a subsequent process of making other data placeholders, as shown in FIG. 44.

2) The visualization area cooperates with the rendering area and the viewing area.

The data placeholder in the visualization area is clicked, the input box is opened in the rendering area, and information on the data placeholder is displayed in the input box. When the information on the data placeholder in the input box of the rendering area is modified, modified content is synchronized to the visualization area and the viewing area.

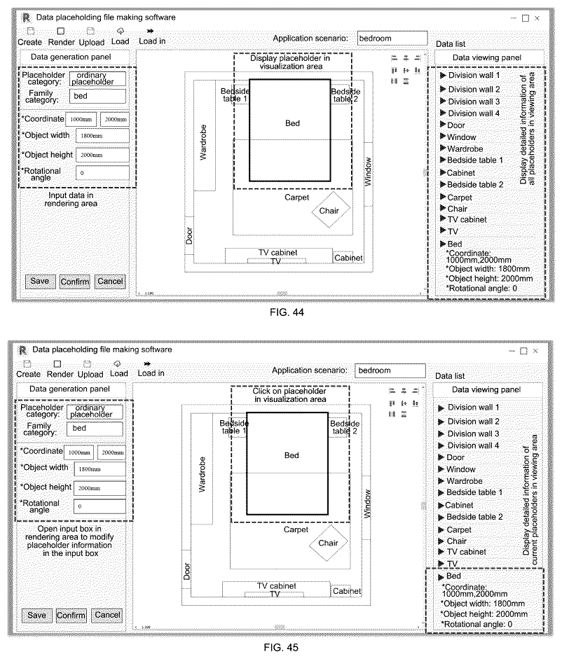

The data placeholder in the visualization area is clicked, and all detailed information on the data placeholder is displayed in the viewing area, including specific coordinates, angle and other information. By this method, the correctness of the data placeholder rendering information can be checked, as shown in FIG. 45.

3) The viewing area cooperates with the rendering area and the visualization area.

By clicking the data placeholder information in the viewing area, the same data placeholder can be positioned in the rendering area and the visualization area, so as to modify the same in the rendering area or check the same in the visualization area.

After a new data placeholding file is created or the historical data placeholding file is loaded and the data placeholder is adjusted, it can be saved as a local file or uploaded to the placeholder storage database. After being stored, the data placeholding file can be used repeatedly.

The format of saving the data placeholding file is the same as the JSON file format described above.

Based on the above, a recommended BIM component file can be obtained from the digital design resource library based on the data placeholder in the data placeholding file, and this step can be realized in the following manner:

reading BIM component type and application scenario corresponding to the data placeholder in the data placeholding file; retrieving in the digital design resource library for keywords containing the BIM component type and application scenario; obtaining a plurality of candidate BIM component files corresponding to the data placeholder based on the retrieved keywords; and determining the recommended BIM component file from the plurality of candidate BIM component files.

The data placeholding file has all information except the BIM component file and level. When building the standard unit, the program gives each data placeholder one BIM component file, so that the BIM component instance can be placed in the current level. Therefore, one BIM component file needs to be recommended to each data placeholder.

A specific recommending method is as follows: reading BIM component type and application scenario in all data placeholder information at a rear end of a plug-in, and retrieving keywords containing the BIM component type and application scenario of each data placeholder in the digital design resource library through C# program. Each data placeholder will have multiple candidate BIM component files, and the program selects a first BIM component therein and binds the same to the data placeholder as the recommended BIM component file.

On this basis, the standard unit can be made based on the data placeholder and the corresponding recommended BIM component file, specifically:

acquiring data placeholders under all data placeholder categories, and acquiring the recommended BIM component file corresponding to the data placeholder under each data placeholder category; and with regard to the data placeholders of a plurality of categories and corresponding recommended BIM component files, placing BIM component instances based on the data placeholders of various categories and corresponding recommended BIM component files in turn according to a set sequence, so as to complete the making of the standard unit.

The mentioned standard unit is a BIM model formed by combining a group of related BIM components, which is mapped to an application scene in real life, such as standard room, standard toilet, standard nurse station, standard medical unit, and standard office unit. A BIM component instance can be selected from the standard unit for replacement of the BIM component, so as to adjust an inherent expression form of the standard unit. After the data placeholding file is created and the BIM component file of each data placeholder is recommended, the standard unit finally can be made. By clicking “Load in” of the plug-in, the standard unit can be automatically made in the Revit. Specific steps are as follows:

first step: acquiring all data placeholder information by a program rear end, including the first-class placeholder, the second-class placeholder, the third-class placeholder, and the fourth-class placeholder;

second step: acquiring the BIM component files bound to all the data placeholders by the program rear end; and

third step: making the standard unit, wherein the sequence of placing the BIM component instances is placing the BIM component instance of the first-class placeholder, and then successively instances of the fourth-class placeholder, the second-class placeholder, and the third type of placeholder.

In the above, for the first-class placeholder, the wall is automatically arranged using Revit API. First, a wall line in a Line format is created using the start point of the wall and the end point of the wall, then, by calling FilteredElementCollector class, current level and a system BIM component of the wall are acquired using a function OfCategoryId( ) in the FilteredElementCollector class, and finally, the wall is placed at the current level of the Revit using a function Wall.Create( ).

In the above, for the fourth-class placeholder, theFilteredElementCollector class is called, the current level is acquired through the function OfCategoryId( ) in the FilteredElementCollector class, the DRAM component file is loaded in through a function Directory.GetFiles( ) and a function Document.LoadFamily( ), and then a coordinate point, the level, and the BIM component file are put into a function Document.Create.NewFamilyInstance( ), so that the BIM component instance can be created.

In the above, for the second-class placeholder, the BIM component instance is automatically placed using the Revit API. The program first captures a host element in the Revit using the host element ID stored in the second-class placeholder, then acquires the current level through the function OfCategoryId( ) in the FilteredElementCollector class, and loads the BIM component file through the functions Directory.GetFiles( ) and the Document.LoadFamily( ). Finally, the second-class placeholder can be placed by placing the coordinate point, the loaded BIM component file, the captured host element, and the current level into the function Document.Create.New Family Instance( ).

In the above, for the third-class placeholder, the method of automatically placing the BIM component instance using the Revit API is similar to that of the second-class placeholder. A z value given to coordinate point XYZ in the function Document. Create.NewF amilyInstance( ) is height.

In the present embodiment, if the above process is understood as a development process, the plug-in for building the BIM model can be developed in the above manner, and this plug-in can be placed in the BIM software in the present disclosure, i.e., the Revit software.

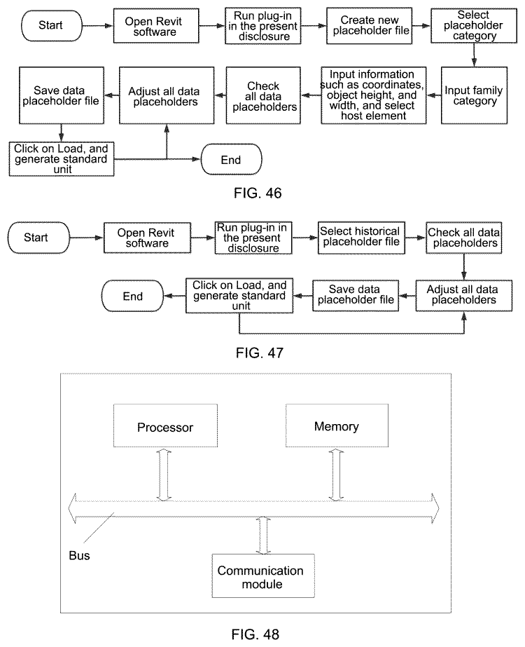

On the basis of the above, when the plug-in is applied, referring to FIG. 46, when a newly created data placeholding file is used to generate the standard unit, it can be realized through the following steps:

1) opening the plug-in in the present disclosure in the Revit, and clicking to create a new placeholder file;

2) inputting information required by the data placeholder: selecting a placeholder category, inputting information such as BIM component category, coordinates, object width, and object height, and clicking on the host element;

3) checking all data placeholders, and adjusting the same;

4) saving the data placeholder file;

5) loading the data placeholders into the Revit, and generating a standard unit;

6) adjusting the data placeholders, and generating a new standard unit; and

7) ending.

In addition, for the application of the above plug-in, referring to FIG. 47, in the manner of making the standard unit with the historical data placeholding file, it can be realized in the following manner:

1) opening the plug-in in the present disclosure in the Reivt, and selecting a historical placeholder file;

2) checking all data placeholders, and adjusting the data placeholders;

3) saving the data placeholder file;

4) loading the data placeholders into the Revit, and generating a standard unit;

5) adjusting the data placeholders, and generating a new standard unit; and

6) ending.

To sum up, the digital design resource library application method provided in the embodiments of the present disclosure includes creating a BIM component in a plurality of different creating modes, such as the mode based on automatic extraction by BIM model, the BIM component creating mode based on a recommended creation order, and the BIM component creating mode based on Rhino component conversion. The problems in the prior art, such as domination of autonomous creation, and low creation efficiency of the BIM component resource due to the complicated operation steps, failing to effectively utilize the component resources in the existing BIM model, and the lack of an effective method of converting other non-BIM component resources to BIM component resources, can be solved targetedly.

Besides, in the present embodiment, batch addition of parameters also can be performed on the BIM component, so as to realize modification of the BIM component. The problem of low efficiency existing in the batch addition to a single component in the mode of adding parameters to the BIM component in the prior art can be solved pertinently.

Further, in the present embodiment, the parameter visualization verification can also be performed on the BIM component, so as to targetedly solve the problem in the prior art that there is no effective verification method for a created BIM component, in particular, the verification of the parameterization capability of the BIM component has low efficiency.

In addition, the present embodiment further provides a BIM component recommending method based on cosine similarity, which can targetedly solve the defects of depending on autonomic search and query of the designer and lacking an effective manner for recommended use of the BIM component in the prior art.

Further, the present embodiment further provides a BIM model building method based on data placeholding, which can targetedly solve the defects such as long time consumption and high multiplexing difficulty when building a BIM model with a single BIM component in the prior art.

To sum up, the digital design resource library application method provided in the embodiments of the present disclosure as a whole can solve the defects of immaturity of the building-related BIM component resource library, and lack of systematicness in terms such as formation, management, and application of the BIM component resource library in the prior art.

Referring to FIG. 48, it is a structural block diagram of electronic equipment provided in an embodiment of the present disclosure, wherein the electronic equipment includes a memory, a processor, and a communication module. Various elements of the memory, the processor, and the communication module are electrically connected to each other directly or indirectly, so as to realize transmission or interaction of data. For example, electrical connections between these elements can be realized via one or more communication buses or signal lines.

In the above, the memory is configured to store program or data. The memory may be, but is not limited to, random access memory (RAM), read only memory (ROM), programmable read-only memory (PROM), erasable programmable read-only memory (EPROM), electric erasable programmable read-only memory (EEPROM) and so on.

The processor is configured to read/write data or program stored in the memory, and execute the BIM component creating method and the digital design resource library application method provided in any embodiment of the present disclosure.

The communication module is configured to establish a communication connection between the electronic equipment and other communication terminals via a network, and is configured to send and receive data via the network.

It can be understood that the structure shown in FIG. 48 is merely an exemplary structural schematic diagram of the electronic equipment, while the electronic equipment further may include more or less assemblies than those shown in FIG. 48, or is configured in a way different from that shown in FIG. 48.

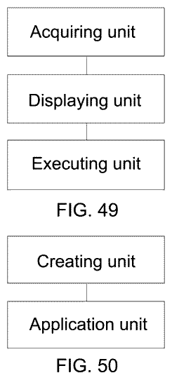

Besides, referring to FIG. 49, an embodiment of the present disclosure further provides a BIM component creating device, wherein the device includes:

an acquiring unit, configured to acquire recommended creation orders based on a current creation order and transition probability information for creating a BIM component,

wherein the transition probability information includes execution probability of any next creation order after the current creation order, and the recommended creation orders include first preset number of creation orders ranked from high execution probability to low execution probability;

a displaying unit, configured to display the recommended creation orders in a recommendation interface; and

an executing unit, configured to, when any one of the recommended creation orders is determined as a new creation order, execute the new creation order.

The BIM component creating device based on a recommended creation order in the embodiments of the present disclosure can realize the BIM component creating method based on the recommended creation order in any implementation mode in the above. For details not described in the present embodiment, reference can be made to relevant description of the BIM component creating method based on a recommended creation order in the above embodiments.

Besides, referring to FIG. 50, an embodiment of the present disclosure further provides a digital design resource library application device, wherein the device includes:

a creating unit, configured to create a BIM component in a plurality of different creating modes, wherein the plurality of different creating modes include a BIM component creating mode based on automatic extraction by BIM model, a BIM component creating mode based on Rhino component conversion, and the above creating mode realized by the BIM component creating device based on a recommended creation order; and

an application unit, configured to perform, for a BIM component to which parameters need to be added, bulk addition of parameters on the BIM component, and after a creator performing geometric parameter binding on the BIM component to which the parameters are added, perform geometric parameter visualization verification on the BIM component, and store the verified BIM component in a digital design resource library.

The digital design resource library application device in the embodiments of the present disclosure can realize the digital design resource library application method in any implementation mode in the above. For details not described in the present embodiment, reference can be made to the relevant description of the digital design resource library application method in the above embodiments.

Further, an embodiment of the present disclosure further provides a computer-readable storage medium stored with a computer-executable order, and when the computer-executable order is executed, the BIM component creating method and the digital design resource library application method in the above embodiments are realized.

Specifically, the computer-readable storage medium can be a general-purpose storage medium, for example, removable disk, and hard disk, and when the computer program on the computer-readable storage medium is run, the BIM component creating method and the digital design resource library application method in the above can be executed. When the computer-readable storage medium and the executable orders therein are run, for processes involved, reference can be made to relevant description in the above method embodiments, and details are not described herein again.

The above-mentioned are merely specific embodiments of the present disclosure, but the scope of protection of the present disclosure is not limited thereto, and any modification or substitution that can be easily envisaged by a person skilled in the present technical field within the technical scope disclosed in the present disclosure should fall within the scope of protection of the present disclosure. Therefore, the scope of protection of the present disclosure should be based on the scope of protection of the claims.

1. A BIM component creating method, wherein the method comprises:
acquiring recommended creation orders based on a current creation order and transition probability information for creating a BIM component, wherein
the transition probability information comprises execution probability of any next creation order after the current creation order, and the recommended creation orders comprise first preset number of creation orders ranked from high execution probability to low execution probability;
displaying the recommended creation orders in a recommendation interface; and
when any one of the recommended creation orders is determined as a new creation order, executing the new creation order.

2. The BIM component creating method according to claim 1, wherein before the step of acquiring recommended creation orders based on a current creation order and transition probability information for creating a BIM component, the method further comprises:
acquiring a log record of BIM component creation of a creator, wherein
the log record comprises historical creation orders used by the creator in a process of creating the BIM component and a sequence of executing the historical creation orders;
determining all historical creation orders based on the log record;
counting a frequency of occurrence of any order combination in the log record, wherein the order combination is a combination of any two adjacent historical creation orders;
counting the number of combinations corresponding to any historical creation order in the log record, wherein the number of combinations is the number of order combinations with the historical creation order as a first order therein; and
based on the frequency and the number of combinations, determining execution probability of any historical creation order after each historical creation order, so as to generate the transition probability information.

3. The BIM component creating method according to claim 2, wherein the step of acquiring a log record of BIM component creation of a creator comprises:
reading a log file in a designated path, acquiring a line text beginning with a specified character string in the log file, and generating a corresponding log record;
in cases where the log record contains a first feature character string or does not contain a second feature character string, deleting the log record; and
deleting a first line in the log record retained.

4. A digital design resource library application method, wherein the method comprises:
creating a BIM component in a plurality of different creating modes, wherein the plurality of different creating modes comprise a BIM component creating mode based on automatic extraction by a BIM model, a BIM component creating mode based on Rhino component conversion, and the BIM component creating method according claim 1; and
performing, for a BIM component to which parameters need to be added, bulk addition of parameters on the BIM component, after a creator performing geometric parameter binding on the BIM component to which the parameters are added, performing geometric parameter visualization verification on the BIM component, and storing a verified BIM component in a digital design resource library.

5. The digital design resource library application method according to claim 4, wherein the method further comprises a step of recommending a BIM component based on a cosine similarity, and the step comprises:
acquiring a preset BIM model, and creating a first data section based on first BIM components in the preset BIM model, wherein the first BIM components are BIM components in the digital design resource library;
acquiring a first BIM component dataset based on the first data section, and storing the first BIM component dataset;
in response to a selection operation for a target insertion point, creating a second data section with the target insertion point as a center;
acquiring second BIM components in the second data section, and acquiring a second BIM component dataset based on the second BIM components;
performing cosine similarity calculation on the second BIM component dataset and the first BIM component dataset, to obtain a calculation result; and
based on the calculation result, determining a third BIM component having the highest cosine similarity with the second BIM component dataset from the first BIM component dataset, and recommending the third BIM component.

6. The digital design resource library application method according to claim 4, wherein the method further comprises a step of building a BIM model based on data placeholding, and the step comprises:
obtaining a data placeholding file, and adjusting data placeholders in the data placeholding file;
based on the data placeholders in the data placeholding file, obtaining a recommended BIM component file from a digital design resource library; and
obtaining a standard unit based on the data placeholders and a corresponding recommended BIM component file, wherein the standard unit is a BIM model formed by combining a group of related BIM components.

7. The digital design resource library application method according to claim 4, wherein the BIM component creating mode based on automatic extraction by a BIM model comprises following steps:
saving a loadable BIM component file in an archived BIM model as a local file, so as to obtain a first component set, and obtaining MD5 codes and names of all first components in the first component set;
obtaining all BIM components in the digital design resource library to form a second component set, and obtaining MD5 codes and names of all second components in the second component set;
performing full matching on the MD5 codes and the names on all of the first components and the second components; and
for each of the first components, when the MD5 codes and the names of the first components are not successfully matched, examining and modifying the first components, to obtain BIM components passing an examination.

8. The digital design resource library application method according to claim 7, wherein the BIM component creating mode based on automatic extraction by a BIM model further comprises following steps:
when one of an MD5 code and a name of a first component being successfully matched with that of any second component, the second component being a component of the same type as the first component; and
acquiring a parameter set and a sum formula database of the component of the same type, and binding the parameter set and the sum formula database with the first component, so as to write the parameter set and the sum formula database into the first component.

9. The digital design resource library application method according to claim 4, wherein the BIM component creating mode based on Rhino component conversion comprises following steps:
converting a component file comprising Rhino component to an intermediate file having an intermediate format; and
parsing the intermediate file based on Dynamo, and generating a BIM component file, wherein the BIM component file comprises a BIM component corresponding to the Rhino component in the component file.

10. The digital design resource library application method according to claim 9, wherein the step of converting a component file comprising Rhino component to an intermediate file having an intermediate format comprises:
acquiring all component files according to an acquired folder path saving the component file comprising the Rhino component, and saving the component files in a file list; and
capturing the Rhino component in the component file from the file list by a selection command, converting a format of the Rhino component to the intermediate format, and storing a converted component in an obtained folder path for storing the intermediate file.

11. The digital design resource library application method according to claim 9, wherein the step of parsing the intermediate file based on Dynamo, and generating a BIM component file comprises:
based on a code block in the Dynamo, after acquiring all intermediate files, recording points and surfaces of components in each of the intermediate files;
traversing the surfaces in the intermediate files, combining all the surfaces to obtain a geometry, and storing the geometry in a geometry list; and
creating a blank BIM component template file, and generating the BIM component file based on the geometry list saving the geometry and the BIM component template file.

12. The digital design resource library application method according to claim 4, wherein the step of performing bulk addition of parameters on the BIM component comprises:
acquiring a batch of BIM component files comprising BIM components to which parameters need to be added;
eliminating repeated BIM component files among all acquired BIM component files, and eliminating a BIM component file of which version information is higher than current version information of a BIM software;
acquiring a batch of parameters used for parameter addition, and storing the parameters in a parameter list; and
adding all acquired parameters in batch to all the BIM component files.

13. The digital design resource library application method according to claim 12, wherein the step of adding all acquired parameters in batch to all the BIM component files comprises:
determining one target BIM component file from all BIM component files to be added with parameters, wherein the target BIM component file comprises at least one BIM component;
in cases where the parameter list further comprises any parameter in a to-be-added state, selecting one parameter in the to-be-added state as a target parameter;
in cases where no target parameter in the target BIM component file exists, adding the target parameter to the target BIM component file, and modifying the target parameter to be in an added state;
determining whether the parameter list further comprises a parameter in the to-be-added state;
when the parameter in the to-be-added state being further comprised, repeatedly selecting one parameter in the to-be-added state as the target parameter, until all parameters in the parameter list are in the added state;
when all the parameters in the parameter list being in the added state, modifying the target BIM component file to be in the added state;
determining whether a BIM component file to be added with parameters still exists; and
if so, modifying all the parameters in the parameter list into the to-be-added state, and repeatedly determining one target BIM component file from the BIM component files to be added with parameters, until all the BIM component files complete the parameter addition.

14. The digital design resource library application method according to claim 13, wherein the step of adding the target parameter to the target BIM component file comprises:
mapping the target parameter based on a preset mapping function, so as to obtain a mapping value;
determining the target parameter as a shared parameter or a family parameter;
when the target parameter is the shared parameter, adding the mapping value to the target BIM component file based on a shared parameter function; and
when the target parameter is the family parameter, adding the mapping value to the target BIM component file based on a family parameter function.

15. The digital design resource library application method according to claim 13, wherein after the step of selecting one parameter in the to-be-added state as a target parameter, the step of adding all acquired parameters in batch to all the BIM component files further comprises:
acquiring parameter names of all existing parameters in the target BIM component file;
determining whether a parameter name of the target parameter is the same as a parameter name of any existing parameter in the target BIM component file;
if so, determining that the target parameter exists in the target BIM component file;
in cases where the target parameter exists in the target BIM component file, modifying the target parameter to be in the added state; and
if not, determining that the target parameter is not present in the target BIM component file.

16. The digital design resource library application method according to claim 4, wherein the step of performing geometric parameter visualization verification on the BIM component comprises:
acquiring a BIM component parameter of a to-be-verified BIM component, and acquiring a target parameter corresponding to each preset target parameter type in the BIM component parameter;
creating a target visualization interface comprising target parameter types and the target parameter corresponding to each target parameter type using a drive verification software, wherein the target visualization interface is located above the to-be-verified BIM component corresponding to the BIM component parameter, and a geometry of the to-be-verified BIM component can be synchronously adjusted with adjustment of the target parameter; and
by adjusting the target parameter in the target visualization interface, realizing synchronous adjustment of the geometry of the to-be-verified BIM component, so as to complete visualization verification of parameterization capability of the to-be-verified BIM component.

17. The digital design resource library application method according to claim 16, wherein the step of by adjusting the target parameter in the target visualization interface, realizing synchronous adjustment of the geometry of the to-be-verified BIM component, so as to complete visualization verification of parameterization capability of the to-be-verified BIM component comprises:
adjusting a target parameter adjustment sliding block of the target parameter in the target visualization interface, and obtaining a change situation of the geometry of the to-be-verified BIM component after each time of adjustment; and
judging whether the change situation satisfies an expected result, if not, modifying the to-be-verified BIM component, and if satisfying, ending a verification process, so as to complete the visualization verification of the parameterization capability of the to-be-verified BIM component.

18. The digital design resource library application method according to claim 17, wherein the method further comprises a step of developing the drive verification software, and the step comprises:
acquiring all BIM component parameters of the BIM component, and constituting a parameter set with the BIM component parameters according to a preset format;
screening out a target parameter corresponding to a set parameter type in the parameter set, and constituting a target parameter set with the target parameter corresponding to the parameter type;
correspondingly creating a BIM component parameter sub-group of the visualization interface according to the parameter type, wherein the BIM component parameter sub-group comprises at least one target parameter of a parameter type corresponding thereto;
creating the target parameter adjustment sliding block corresponding to the target parameter in the BIM component parameter sub-group of the visualization interface;
binding the target parameter with the corresponding target parameter adjustment sliding block, to obtain the visualization interface comprising the BIM component parameter sub-group and the target parameter set, wherein the BIM component parameter sub-group carries information on the parameter type; and
synchronously adjusting the geometry of the BIM component by adjusting the target parameter in the visualization interface, and performing drive verification on the parameterization capability of the BIM component, so as to complete a development of the drive verification software.

19. The digital design resource library application method according to claim 5, wherein the preset BIM model contains several first BIM components; and
the step of acquiring a preset BIM model, and creating a first data section based on first BIM components in the preset BIM model comprises:
acquiring the preset BIM model;
traversing the preset BIM model, and acquiring all of the first BIM components in the preset BIM model;
determining a first operation view of the first BIM components according to the first BIM components; and
creating the first data section with the first BIM components in the first operation view as a center.

20. A BIM component creating device, wherein the device comprises:
an acquiring unit, configured to acquire recommended creation orders based on a current creation order and transition probability information for creating a BIM component, wherein
the transition probability information comprises execution probability of any next creation order after the current creation order, and the recommended creation orders comprise first preset number of creation orders ranked from high execution probability to low execution probability;
a displaying unit, configured to display the recommended creation orders in a recommendation interface; and
an executing unit, configured to, when any one of the recommended creation orders is determined as a new creation order, execute the new creation order.
